(19) United States
(12) Patent Application Publication
(10) Pub. No.: US 2009/0073356 A1
(43) Pub. Date: Mar. 19, 2009

(54) COLOR FILTER INK, COLOR FILTER, IMAGE DISPLAY DEVICE, AND ELECTRONIC DEVICE

(75) Inventors: Hidekazu Moriyama, Fujimi-machi (JP); Masaya Shibatani, Matsumoto (JP); Hiroshi Kiguchi, Suwa (JP)

Correspondence Address: GLOBAL IP COUNSELORS, LLP, 1233 20TH STREET, NW, SUITE 700, WASHINGTON, DC, 20036-2680, US

(73) Assignee: SEIKO EPSON CORPORATION, Tokyo (JP)

(21) Appl. No.: 12/202,592

(22) Filed: Sep. 2, 2008

(30) Foreign Application Priority Data
Sep. 19, 2007 (JP) 2007-241925

(51) Int. Cl. G02F 1/1335; C08L 27/12; G03F 1/00

(52) U.S. Cl. 349/106; 524/520; 430/7

(57) ABSTRACT

A color filter ink is adapted to be used to manufacture a color filter by an inkjet method. The color filter ink includes a colorant, a resin material, and a liquid medium that dissolves and/or disperses the colorant. The resin material includes a first polymer and a second polymer. The first polymer includes at least a first epoxy-containing vinyl monomer as a monomer component, and the second polymer includes at least a fluoroalkyl- or fluoroaryl-containing vinyl monomer as a monomer component, which is absent from the first polymer.

### CROSS-REFERENCE TO RELATED APPLICATIONS

This application claims priority to Japanese Patent Application No. 2007-241925 filed on Sep. 19, 2007. The entire disclosure of Japanese Patent Application No. 2007-241925 is hereby incorporated herein by reference.

### BACKGROUND

1. Technical Field

The present invention relates to a color filter ink, a color filter, an image display device, and an electronic device.

2. Related Art

Color filters are generally used in liquid crystal display devices (LCD) and the like that display color.

Color filters have conventionally been manufactured using a so-called photolithography method in which a coating film composed of a material (color layer formation composition) that includes a colorant, a photosensitive resin, a functional monomer, a polymerization initiator, and other components is formed on a substrate, and then photosensitive processing for radiating light via a photomask, development processing, and the like are performed. In such a method, the color filters are usually manufactured by repeating a process in which a coating film corresponding to each color is formed on substantially the entire surface of the substrate, only a portion of the coating film is cured, and most of the film other than the cured portion is removed, so that there is no color overlap. Therefore, only a portion of the coating film formed in color filter manufacturing remains as a color layer in the finished color filter, and most of the coating film is removed in the manufacturing process. Therefore, not only does the manufacturing cost of the color filter increase, but the process is also undesirable from the perspective of resource saving.

On the other hand, Japanese Laid-open Patent Application No. 2002-372613 discloses a method for forming the color layer of a color filter through the use of an inkjet head (droplet discharge head). In such a method, because the discharge position and the like of droplets of the material (color layer formation composition) used to form the color layer are easily controlled, and waste of the color layer formation composition can be reduced, the environmental impact can be reduced, and manufacturing cost can also be minimized. However, in a method for manufacturing a color filter using an inkjet head, when droplets are discharged for long periods of time, and droplets are discharged continuously, the trajectory of the discharged droplets changes (so-called flight deflection occurs), it becomes impossible to land the droplets in the desired region, the droplet discharge quantity becomes unstable, and other problems occur. When such problems occur, on the substrate or the like onto which the droplets are to be discharged, the plurality of types of ink used to form different colored portions mixes together (colors mix), and the color saturation fluctuates between the plurality of colored portions that are originally supposed to have the same color saturation, and as a result, uneven color between regions of the same color filter, uneven saturation, and the like occur, fluctuation occurs in the characteristics (particularly contrast ratio, color reproduction range, and other color characteristics) between numerous color filters, and the reliability of the color filters is reduced. Since the droplet discharge device (industrial) used for color filter manufacturing is entirely different from what is used for a printer (consumer-level), and the droplet discharge device is used for mass production and droplet discharge onto large-scale workpieces (substrates), for example, there is a need to discharge large quantities of droplets for long periods of time. Because the droplet discharge device is used under such harsh conditions, the droplet discharge quantity easily fluctuates in comparison to a consumer droplet discharge device, but when the discharge quantity varies in this manner, fluctuation of the characteristics between numerous manufactured color filters, or fluctuation in the color saturation in different areas of a color filter occurs, and the reliability of the color filter as a product is markedly reduced.

There has been a recent trend of using color filter inks that have a high colorant content in order to ensure a wider range of color reproduction in color filters, but such problems as those described above become more severe as the colorant content increases.

There has also been a recent trend of increasing the luminance of the display image in order to achieve even higher image quality in liquid crystal display devices (LCD) and the like that display color. There is a need for enhanced durability of color filters to accompany the increased luminance.

### SUMMARY

One object is to provide an inkjet-type color filter ink that has excellent discharge stability and excellent uniformity of characteristics between units, in which unevenness of color and saturation among regions is suppressed, that can be suitably used to manufacture a color filter having excellent durability; and to provide a color filter having excellent durability and excellent uniformity of characteristics between individual units, and in which unevenness of color saturation between different regions is suppressed; and to provide an image display device and electronic device provided with the color filter.

In order to achieve the object described above, a color filter ink according to one aspect is adapted to be used to manufacture a color filter by an inkjet method. The color filter ink includes a colorant, a resin material, and a liquid medium that dissolves and/or disperses the colorant. The resin material includes a first polymer and a second polymer. The first polymer includes at least a first epoxy-containing vinyl monomer as a monomer component and not including a fluoroalkyl- or fluoroaryl-containing vinyl monomer represented by a chemical formula (1) below as a monomer component. The second polymer includes at least the fluoroalkyl- or fluoroaryl-containing vinyl monomer represented by the chemical formula (1) below as a monomer component.

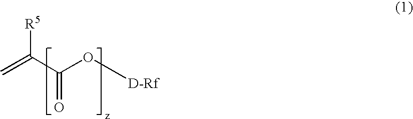

In the chemical formula (1), R⁵ represents a hydrogen atom or a C₁₋₇ alkyl group, D represents a single bond hydrocarbon group, a bivalent hydrocarbon group, or a bivalent hydrocarbon group having a hetero atom, Rf represents a C₁₋₂₀ fluoroalkyl group or fluoroaryl group, and a value z is 0 or 1.

It is thereby possible to provide an inkjet-type color filter ink that can be suitably used to manufacture a color filter, and that has excellent discharge stability and excellent durability and uniformity of characteristics between individual units, and in which unevenness of color saturation between different regions is suppressed.

In the color filter ink as described above, the first polymer is preferably a copolymer having the first epoxy-containing vinyl monomer and a second vinyl monomer as monomer components, the second vinyl monomer having an isocyanate group or a block isocyanate group in which an isocyanate group is protected by a protective group.

It is thereby possible to effectively prevent the color of the color filter (colored portion) manufactured using the color filter ink from changing over time, and to endow the color filter with particularly excellent durability.

In the color filter ink as described above, the first polymer preferably includes 2 to 20 parts by weight of the second vinyl monomer with respect to 100 parts by weight of the first epoxy-containing vinyl monomer.

The durability of the color filter manufactured using the color filter ink can thereby be made particularly excellent while making the discharge stability of the color filter ink particularly excellent.

In the color filter ink as described above, the first polymer is preferably a copolymer having the first epoxy-containing vinyl monomer and a third vinyl monomer as monomer components, the third vinyl monomer having a hydroxyl group.

The adhesion to the color filter substrate of the colored portion of the color filter formed using the color filter ink can thereby be reliably maintained over a longer period of time, and the durability of the color filter can be made particularly excellent.

In the color filter ink as described above, the first polymer preferably includes 2 to 20 parts by weight of the third vinyl monomer with respect to 100 parts by weight of the first epoxy-containing vinyl monomer.

The durability of the color filter manufactured using the color filter ink can thereby be made particularly excellent while making the discharge stability of the color filter ink particularly excellent.

In the color filter ink as described above, a ratio of a content of the first polymer to a content of the second polymer is preferably 25:75 to 75:25 in terms of weight.

The discharge stability of the color filter ink and the durability of the color filter manufactured using the color filter ink can thereby be made particularly excellent.

In the color filter ink as described above, the liquid medium preferably includes a compound having a propylene glycol backbone and alkoxy groups at both terminal ends of the propylene glycol backbone.

The discharge stability of the color filter ink, and the durability of the color filter manufactured using the color filter ink can thereby be made particularly excellent.

In the color filter ink as described above, the liquid medium preferably includes a mixture of 1,3-butylene glycol diacetate and diethylene glycol monobutyl ether acetate, with a content ratio of 1,3-butylene glycol diacetate and diethylene glycol monobutyl ether acetate being 75:25 to 98:2 in terms of weight.

The discharge stability of the color filter ink, and the durability of the color filter manufactured using the color filter ink can thereby be made particularly excellent.

In the color filter ink as described above, a content ratio of the colorant in the color filter ink is preferably 2 to 25 wt %.

A higher color saturation can thereby be ensured in the color filter manufactured using the color filter ink, and the color filter can be used for more distinct image display. In the prior art, when the colorant (particularly a pigment) is included in a relatively high concentration in this manner, the discharge stability is particularly low, and flight deflection, unstable droplet discharge quantities, and other problems occur particularly easily when droplets of the color filter ink are discharged. However, in the present invention, even when the colorant is included in a relatively high concentration, the occurrence of such problems as those described above can be reliably prevented, and it is possible to reliably prevent the occurrence of uneven color, uneven saturation, and the like between different regions of the manufactured color filter, and fluctuation of characteristics between individual units. Specifically, when the colorant is included in a relatively high concentration, as described above, the effects of the present invention can be more significantly demonstrated. The durability of the manufactured color filter can also be made particularly excellent.

In the color filter ink as described above preferably further includes a dispersing agent including a compound having a cyamelide backbone. The colorant preferably includes a pigment.

The discharge stability of the color filter ink can thereby be made particularly excellent.

A color filter according to another aspect is manufactured using the color filter ink as described above.

It is thereby possible to provide a color filter having excellent durability and excellent uniformity of characteristics between individual units, and in which unevenness of color, saturation, and the like between regions is suppressed.

An image display device according to another aspect has the color filter as described above.

It is thereby possible to provide an image display device having excellent durability and excellent uniformity of characteristics between individual units, and in which unevenness of color, saturation, and the like between regions of the display portion is suppressed.

The image display device as described above is preferably a liquid crystal panel.

It is thereby possible to provide an image display device having excellent durability and excellent uniformity of characteristics between individual units, and in which unevenness of color, saturation, and the like between regions of the display portion is suppressed.

An electronic device according to another aspect includes the image display device as described above.

It is thereby possible to provide an electronic device having excellent durability and excellent uniformity of characteristics between individual units, and in which unevenness of color, saturation, and the like between regions of the display portion is suppressed.

### BRIEF DESCRIPTION OF THE DRAWINGS

Referring now to the attached drawings which form a part of this original disclosure:

FIG. 1 is a partial schematic cross-sectional view of a color filter according to an embodiment of the present invention;

FIG. 2 includes a series of diagrams (1a) to (1e) showing partial schematic cross-sectional views for explaining a method for manufacturing the color filter according to the embodiment of the present invention;

FIG. 3 is a simplified perspective view of a droplet discharge device using in the manufacture of the color filter according to the embodiment of the present invention;

FIG. 4 is a schematic view of a droplet discharge unit in the droplet discharge device shown in FIG. 3, as seen from the stage side according to the embodiment of the present invention;

FIG. 5 is a schematic view showing a bottom surface of a droplet discharge head in the droplet discharge device shown in FIG. 3 according to the embodiment of the present invention;

FIG. 6 includes a pair of diagrams (a) and (b) showing the droplet discharge head in the droplet discharge device shown in FIG. 3, wherein FIG. 6(a) is a cross-sectional perspective view and FIG. 6(b) is a cross-sectional view;

FIG. 7 is a partial schematic cross-sectional view of a liquid crystal display device according to the embodiment of the present invention;

FIG. 8 is a perspective view of a mobile (or notebook) personal computer to which the electronic device of the embodiment of the present invention has been applied;

FIG. 9 is a perspective view of a portable telephone (including PHS) to which the electronic device of the embodiment of the present invention has been applied; and

FIG. 10 is a perspective view of a digital still camera in which the electronic device of the embodiment of the present invention has been applied.

### DETAILED DESCRIPTION OF EXEMPLARY EMBODIMENTS

Preferred embodiments of the present invention will be described in detail hereinafter.

### Color Filter Ink

The color filter ink of the present invention is an ink used to manufacture (form the colored portion of a color filter) a color filter, and is used particularly in the manufacture of a color filter by an inkjet method.

The color filter ink includes a colorant, a resin material, and a liquid medium or the like for dissolving and/or dispersing the colorant.

### Colorant

A color filter usually has a plurality of different colors of colored portions (generally three colors of colored portions corresponding to RGB). The colorant is usually selected according to the hue of the colored portion to be formed. Examples of colorants that can be used to form the color filter ink include various types of pigments and various types of dyes.

Examples of pigments include C. I. pigment red 2, 3, 5, 17, 22, 23, 38, 81, 48:1, 48:2, 48:3, 48:4, 49:1, 52:1, 53:1, 57:1, 63:1, 112, 122, 144, 146, 149, 166, 170, 176, 177, 178, 179, 185, 202, 207, 209, 254, 101, 102, 105, 106, 108, and 108:1; C. I. pigment green 7, 36, 15, 17, 18, 19, 26, and50; C. I. pigment blue 1, 15, 15:1, 15:2, 15:3, 15:4, 15:6, 17:1, 18, 60, 27, 28, 29, 35, 36, and 80; C. I. pigment yellow 1, 3, 12, 13, 14, 17, 55, 73, 74, 81, 83, 93, 94, 95, 97, 108, 109, 110, 129, 138, 139, 150, 151, 153, 154, 168, 184, 185, 34, 35, 35:1, 37, 37:1, 42, 43, 53, and 157; C. I. pigment violet 1, 3, 19, 23, 50, 14, and 16; C. I. pigment orange 5, 13, 16, 36, 43, 20, 20:1, and 104; C. I. pigment brown 25, 7, 11, and 33; and various types of metal derivatives, phthalocyanine compounds, and the like. Among such pigments as those described above, a phthalocyanine compound (phthalocyanine complex), for example, may be used in which the central metal is substituted by another metal atom.

Examples of dyes include azo dyes, anthraquinone dyes, condensed multi-ring aromatic carbonyl dyes, indigoid dyes, carbonium dyes, phthalocyanine dyes, methines, polymethine dyes, and the like. Specific examples of dyes include C. I direct red 2, 4, 9, 23, 26, 28, 31, 39, 62, 63, 72, 75, 76, 79, 80, 81, 83, 84, 89, 92, 95, 111, 173, 184, 207, 211, 212, 214, 218, 221, 223, 224, 225, 226, 227, 232, 233, 240, 241, 242, 243, and 247; C. I. acid red 35, 42, 51, 52, 57, 62, 80, 82, 111, 114, 118, 119, 127, 128, 131, 143, 145, 151, 154, 157, 158, 211, 249, 254, 257, 261, 263, 266, 289, 299, 301, 305, 319, 336, 337, 361, 396, and 397; C. I. reactive red 3, 13, 17, 19, 21, 22, 23, 24, 29, 35, 37, 40, 41, 43, 45, 49, and 55; C. I. basic red 12, 13, 14, 15, 18, 22, 23, 24, 25, 27, 29, 35, 36, 38, 39, 45, and 46; C. I direct violet 7, 9, 47, 48, 51, 66, 90, 93, 94, 95, 98, 100, and 101; C. I acid violet 5, 9, 11, 34, 43, 47, 48, 51, 75, 90, 103, and 126; C. I reactive violet 1, 3, 4, 5, 6, 7, 8, 9, 16, 17, 22, 23, 24, 26, 27, 33, and 34; C. I. basic violet 1, 2, 3, 7, 10, 15, 16, 20, 21, 25, 27, 28, 35, 37, 39, 40, and 48; C. I. direct yellow 8, 9, 11, 12, 27, 28, 29, 33, 35, 39, 41, 44, 50, 53, 58, 59, 68, 87, 93, 95, 96, 98, 100, 106, 108, 109, 110, 130, 142, 144, 161, and 163; C. I. acid yellow 17, 19, 23, 25, 39, 40, 42, 44, 49, 50, 61, 64, 76, 79, 110, 127, 135, 143, 151, 159, 169, 174, 190, 195, 196, 197, 199, 218, 219, 222, and 227; C. I. reactive yellow 2, 3, 13, 14, 15, 17, 18, 23, 24, 25, 26, 27, 29, 35, 37, 41, and 42; C. I. basic yellow 1, 2, 4, 11, 13, 14, 15, 19, 21, 23, 24, 25, 28, 29, 32, 36, 39, and 40; C. I. acid green 16; C. I. acid blue 9, 45, 80, 83, 90 and 185; C. I. basic orange 21 and 23; and the like.

Inclusion of a pigment as the colorant in the color filter ink is advantageous because the light fastness and thermal resistance of the formed color filter (colored portion) can be enhanced. In the prior art, when the color filter ink includes a pigment as the colorant, the content ratio of gas in the color filter ink readily increases, and as described hereinafter, the problem of reduced discharge stability of the droplets readily occurs. In the present invention, however, such problems can be reliably prevented from occurring even when a pigment is included as the colorant. Specifically, the effects of the present invention can be more significantly demonstrated when the color filter ink includes a pigment as the colorant.

In the conventional color filter ink, when a pigment is included as the colorant, an excellent state of dispersion of the colorant is difficult to maintain over a long period of time, and a color filter having excellent contrast is difficult to stably manufacture over a long period of time. In the present invention, however, since a resin material such as the one described hereinafter is used, excellent mixing stability of the resin material with the colorant (pigment) can be maintained over a long period of time, and a color filter having excellent contrast can be stably manufactured over a long period of time. Since the color filter ink, once prepared, can be suitably used for a long time, the frequency of replacing the color filter ink and replacing the color filter ink in the droplet discharge device can be reduced. The color filter can therefore be manufactured with particularly excellent productivity, and the consistency of quality of the manufactured color filter is enhanced.

A powder composed of a material such as described above that is subjected to a lyophilizing treatment (treatment described hereinafter for enhancing affinity to the liquid medium) or other surface treatment may be used as the colorant. The dispersion properties and dispersion stability of the colorant particles in the color filter ink, for example, can thereby be made particularly excellent. Examples of the surface treatment performed on the colorant include modifying the surfaces of the colorant particles using a polymer, and other treatments. Examples of the polymer for modifying the surfaces of the colorant particles include polymers disclosed in Japanese Laid-open Patent Application No. 8-259876 and other publications, various types of commercially available polymers or oligomers for pigment dispersion, and the like.

For example, two or more types of components selected from the above examples may also be combined and used as the colorant.

In the color filter ink, the colorant may be dissolved in the liquid medium described hereinafter, or may be dispersed, but when the colorant is dispersed in the liquid medium, the average grain size of the colorant (pigment particles) is preferably 20 to 200 nm, and more preferably 30 to 180 nm. The dispersion stability of the colorant in the color filter ink, the coloration properties in the color filter, or other characteristics can thereby be made particularly excellent while making the light fastness of the color filter manufactured using the color filter ink adequately superior.

The content ratio of the colorant in the color filter ink is preferably 2 to 25 wt %, and more preferably 3 to 20 wt %. When the content ratio of colorant is within this range, a higher color saturation can be maintained in the color filter manufactured using the color filter ink, and the color filter can be used for more distinct image display. In the conventional technique, when the colorant (particularly a pigment) is included in such a relatively high concentration, the discharge stability is particularly low, and flight deflection, instability of the droplet discharge quantity, and other problems occur particularly easily when droplets of the color filter ink are discharged. Also in the conventional technique, such problems as a severe occurrence of defects due to fluctuation of the discharge quantity among different locations on the surface, and marked reduction of production properties of the color filter occurs particularly when droplets are discharged onto a large substrate (e.g., G5 or larger) to form colored portions. In the present invention, however, even when the colorant is included at a relatively high concentration, such problems as those described above can be reliably prevented from occurring, unevenness of color, saturation, and the like in different locations of the manufactured color filter, or fluctuation of characteristics between individual units can be reliably prevented, and a color filter can be manufactured with excellent productivity, as described in detail hereinafter. Specifically, the effects of the present invention are more significantly demonstrated when the color filter ink includes a relatively high concentration of the colorant, as described above. The durability of the manufactured color filter can also be made particularly excellent.

### Resin Material

The color filter ink generally includes a resin material (binder resin) for such purposes as enhancing adhesion of the formed colored portion to the substrate. Solvent resistance is needed in the resin material in order to prevent adverse effects due to chemical application or washing in steps subsequent to the ink application step in an inkjet method. In the conventional color filter ink, however, it is difficult to endow the color filter (colored portion) with adequately excellent durability. In the case of the conventional color filter ink, when droplets are discharged for long periods of time, and droplets are discharged continuously by the inkjet method, the trajectory of the discharged droplets changes (so-called flight deflection occurs), it becomes impossible to land the droplets in the desired region, the droplet discharge quantity becomes unstable, and other problems occur. When such problems occur, on the substrate or the like onto which the droplets are to be discharged, the plurality of types of ink used to form different colored portions mixes together (colors mix), and the color saturation fluctuates between the plurality of colored portions that are originally supposed to have the same color saturation, and as a result, uneven color between regions of the same color filter, uneven saturation, and the like occur, fluctuation occurs in the characteristics (particularly contrast ratio, color reproduction range, and other color characteristics) between numerous color filters, and the reliability of the color filters is reduced. Such problems are particularly severe when droplets are discharged on a large substrate (e.g., G5 or larger) to form colored portions, and these problems cause severe reduction of the color filter production properties (process yield).

The inventors conducted a concentrated investigation aimed at overcoming such problems as those described above. As a result, the inventors discovered that the problems described above can be overcome by including a resin material (binder resin) such as the one described in detail hereinafter in the color filter ink.

The resin material (curable resin material) constituting the color filter ink of the present invention will be described in detail hereinafter.

The resin material in the color filter ink of the present invention includes a polymer A (first polymer) containing at least an epoxy-containing vinyl monomer a1 (first epoxy-containing vinyl monomer) as a monomer component, and a polymer B (second polymer) containing at least a fluoroalkyl- or fluoroaryl-containing vinyl monomer as a monomer component.

### Polymer A

The polymer A contains at least the epoxy-containing vinyl monomer a1 as a monomer component. The polymer A may be composed of essentially a single compound, or may be a mixture of a plurality of types of compounds. However, when the polymer A is a mixture of a plurality of types of compounds, each of the compounds contains at least the epoxy-containing vinyl monomer a1 as a monomer component.

### Epoxy-Containing Vinyl Monomer a1

The polymer A contains at least the epoxy-containing vinyl monomer a1 as a monomer component. Including such an epoxy-containing vinyl monomer a1 as a monomer component makes it possible to easily and reliably introduce an epoxy group into the polymer A. By including the epoxy-containing vinyl monomer a1 as a monomer component, when the color filter ink includes a pigment as the colorant, for example, excellent dispersion stability of the pigment particles in the color filter ink can be obtained, and the color filter ink can be endowed with excellent long-term storage properties and excellent discharge stability. Including the epoxy-containing vinyl monomer a1 as a monomer component also enables the colored portion formed using the color filter ink to have excellent solvent resistance. Including the epoxy-containing vinyl monomer a1 as a monomer component is also useful because the resin material (binder resin) can be cured under relatively mild conditions when a colored portion is formed using the color filter ink, and the formed colored portion is endowed with excellent hardness and other characteristics. When the polymer A includes a vinyl monomer a2 (second vinyl monomer), a vinyl monomer a3 (third vinyl monomer), and other components such as described hereinafter, the polymer can be suitably synthesized, and a polymer A having the desired characteristics can be easily and reliably obtained.

The epoxy-containing vinyl monomer a1 used may have the structure indicated by Formula (2) below, for example. When the epoxy-containing vinyl monomer a1 has such a structure, in a case in which the color filter ink includes a pigment as the colorant, for example, the dispersion stability of the pigment particles in the color filter ink can be made particularly excellent, and the color filter ink can be endowed with excellent long-term storage properties and excellent discharge stability. When the epoxy-containing vinyl monomer a1 has the structure indicated by Formula (2) below, the colored portion formed using the color filter ink can be endowed with even more superior solvent resistance. When the epoxy-containing vinyl monomer a1 has the structure indicated by Formula (2) below, the resin material (binder resin) can be cured under relatively mild conditions when a colored portion is formed using the color filter ink, and the formed colored portion is endowed with excellent hardness and other characteristics. When the epoxy-containing vinyl monomer a1 has such a structure, the polymer A can be endowed with particularly excellent compatibility with the polymer B described hereinafter, and the colored portion formed using the color filter ink can be endowed with particularly high transparency.

Formula (2)

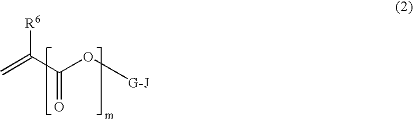

In Formula (2), R⁶ is a hydrogen atom or a C₁₋₇ alkyl group; G is a single bond hydrocarbon group or a bivalent hydrocarbon group which may contain a hetero atom; J is an epoxy group or an alicyclic epoxy group which may have a ring-structured C₃₋₁₀ substituted group; and m is 0 or 1.

In Formula (2), examples of the C₁₋₇ alkyl group indicated by R⁶ include methyl, ethyl, propyl, isopropyl, butyl, isobutyl, s-butyl, pentyl, hexyl, heptyl, and other alkyl groups, but a hydrogen atom or a C₁₋₂ alkyl group is preferred, and a hydrogen atom or a methyl group is more preferred. In a case in which the color filter ink includes a pigment as the colorant, for example, the dispersion stability of the pigment particles in the color filter ink can be made particularly excellent, and the color filter ink can be endowed with excellent long-term storage properties and excellent discharge stability. The contrast of the displayed image can also be made particularly excellent in the manufactured color filter. The colored portion formed using the color filter ink can also be endowed with excellent hardness and other characteristics. The polymer A can also be endowed with particularly excellent compatibility with the polymer B described hereinafter, and the colored portion formed using the color filter ink can be endowed with extremely high transparency.

Typical examples of the bivalent hydrocarbon group indicated by G in Formula (2) that may contain a hetero atom include straight-chain or branched alkylene groups, or more specifically, methylenes, ethylenes, propylenes, tetramethylenes, ethyl ethylenes, pentamethylenes, hexamethylenes, oxymethylenes, oxyethylenes, oxypropylenes, and the like.

Specific examples of the epoxy-containing vinyl monomer a1 include glycidyl(meth)acrylate, methylglycidyl(meth)acrylate, ethylglycidyl(meth)acrylate, glycidyl vinylbenzyl ether (product name: VBGE; manufactured by Seimi Chemical), the alicyclic epoxy-containing unsaturated compounds indicated by Formulas (2-1) through (2-31) below, and the like; and one or more types of these compounds may be selected and used, but (3,4-epoxycyclohexyl)methyl(meth)acrylate is particularly preferred as the epoxy-containing vinyl monomer a1. When a pigment is included as the colorant in the color filter ink, for example, the dispersion stability of the pigment particles in the color filter ink can thereby be made particularly excellent, and the color filter ink can be endowed with excellent long-term storage properties and excellent discharge stability. The colored portion formed using the color filter ink can also be endowed with particularly excellent hardness, solvent resistance, and other characteristics. The polymer A can be endowed with particularly excellent compatibility with the polymer B described hereinafter, and the colored portion formed using the color filter ink can be endowed with extremely high transparency.

Formulas (2-1) Through (2-31)

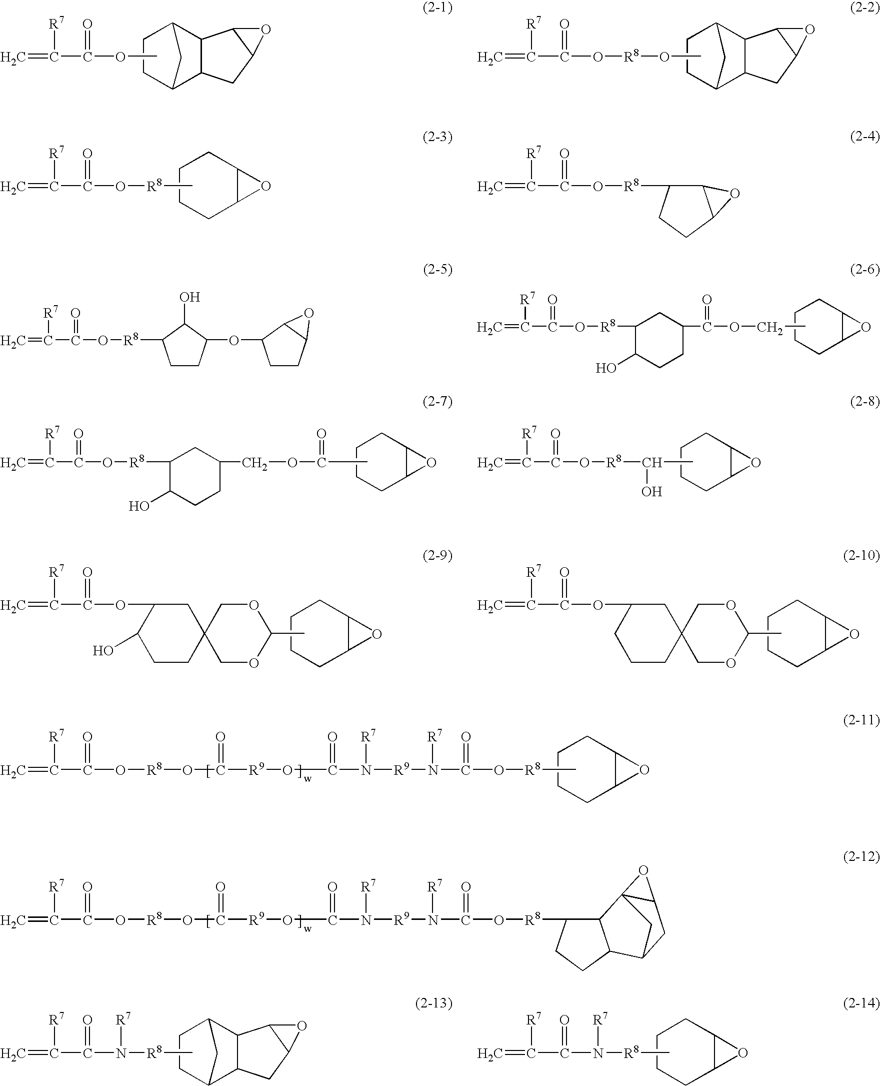

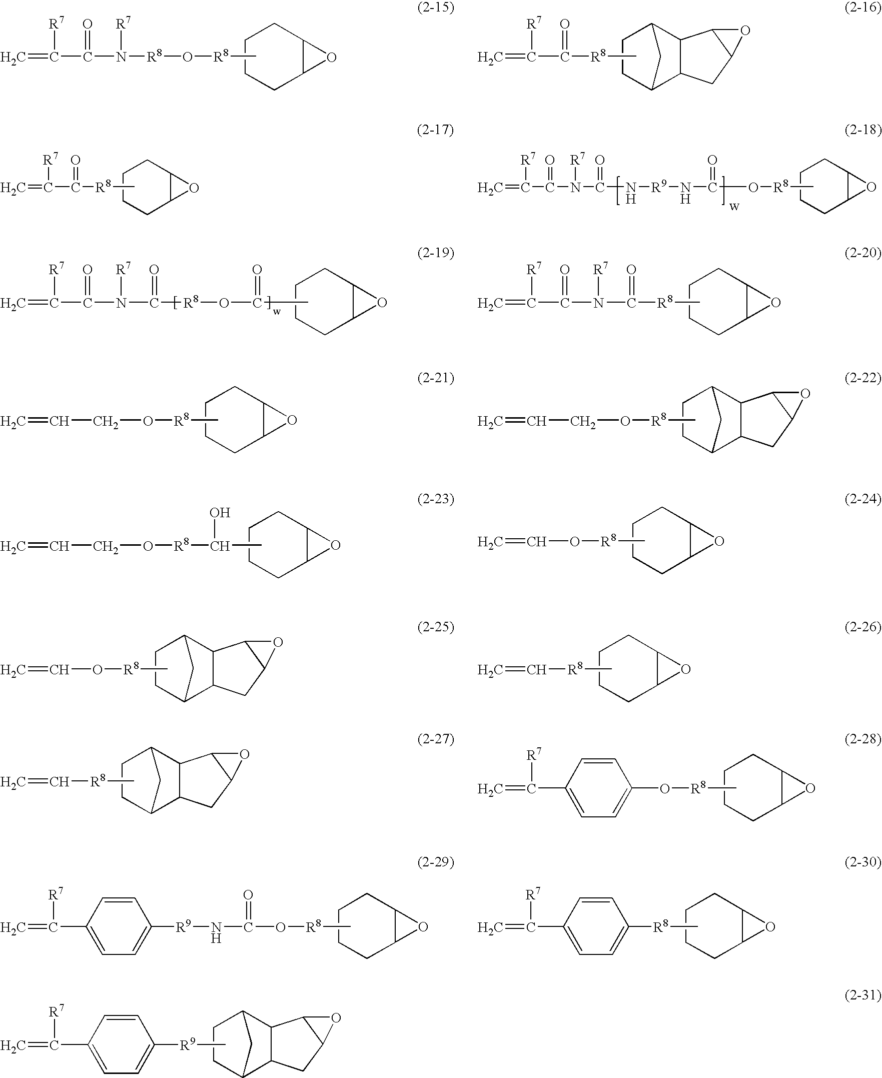

In Formulas (2-1) through (2-31), R⁷ is a hydrogen atom or a methyl group; R⁸ is a C₁₋₈ bivalent hydrocarbon group; and R⁹ is a C₁₋₂₀ bivalent hydrocarbon group. R⁷, R⁸, and R⁹ may be mutually the same or different, and w is 0 to 10.

The content ratio (which is a value obtained by substitution with the weight of the monomer used to synthesize the polymer) of the epoxy-containing vinyl monomer a1 in the polymer A is preferably 50 to 100 wt %, and more preferably 70 to 94 wt %. When the content ratio of the epoxy-containing vinyl monomer a1 in the polymer A is within the aforementioned range, in a case in which the color filter ink includes a pigment as the colorant, the dispersion stability of the pigment particles in the color filter ink can be made particularly excellent, and the color filter ink can be endowed with excellent long-term storage properties and excellent discharge stability. When the content ratio of the epoxy-containing vinyl monomer a1 in the polymer A is within the aforementioned range, the resin material (binder resin) can be cured under relatively mild conditions when a colored portion is formed using the color filter ink, and the formed colored portion is endowed with particularly excellent hardness, solvent resistance, and other characteristics. When the polymer A is a mixture of a plurality of types of compounds, the weighted average value (weighted average value based on weight ratio) of the mixed compounds may be used as the content ratio of the epoxy-containing vinyl monomer a1. When the polymer A is a mixture of a plurality of types of compounds, the compounds all preferably contain the epoxy-containing vinyl monomer a1 in such a content ratio as described above.

### Vinyl Monomer a2

The polymer A may contain at least the epoxy-containing vinyl monomer a1 as a monomer component, but the polymer A is preferably one (a copolymer) containing the epoxy-containing vinyl monomer a1, as well as a vinyl monomer a2 as a monomer group provided with an isocyanate group or a block isocyanate group in which an isocyanate group is protected by a protective group. The content ratio of gas (dissolved gas, bubbles present as microbubbles, or the like) in the color filter ink can thereby be reduced more effectively, and particularly excellent stability of droplet discharge by the inkjet method can be obtained. As a result, it is possible to more effectively prevent the occurrence of uneven color, uneven saturation, and the like between different regions of the manufactured color filter, and fluctuation of characteristics between individual units.

Examples of polymerizable vinyl monomers a2 include 2-acryloyloxyethyl isocyanate (product name: Karenz MOI; manufactured by Showa Denko), 2-methacryloyloxyethyl isocyanate, and other (meth)acryloyl isocyanates and the like in which (meth)acryloyl is bonded with an isocyanate group via a C₂₋₆ alkylene group.

The isocyanate group of the abovementioned (meth)acryloyl isocyanate is preferably a block isocyanate group. The term “block isocyanate group” refers to an isocyanate group in which the terminal end is masked by a blocking agent. Examples of monomers having a block isocyanate group include ethyl 2-(0-[1′-methylpropylideneamino]carboxyamino)methacrylate and the like, and are commercially available under the trade name Karenz MOI-BM, manufactured by Showa Denko. A combination of one or more types of these polymerizable vinyl monomers may be used.

The content ratio (which is a value obtained by substitution with the weight of the monomer used to synthesize the polymer) of the vinyl monomer a2 in the polymer A is preferably 2 to 20 parts by weight, and more preferably 3 to 15 parts by weight, with respect to 100 parts by weight of the epoxy-containing vinyl monomer a1. When the content ratio of the vinyl monomer a2 in the polymer A is within the aforementioned range, the content ratio of gas (dissolved gas, bubbles present as microbubbles, or the like) in the color filter ink can be reduced more effectively, and particularly excellent stability of droplet discharge by the inkjet method can be obtained while the color filter ink is endowed with adequately excellent long-term storage properties and other characteristics. The colored portion formed using the color filter ink can also be endowed with adequately high transparency. In contrast, when the content ratio of the vinyl monomer a2 in the polymer A is less than the lower limit of the aforementioned range, the effects of including a vinyl monomer a2 such as those described above may not be adequately demonstrated. When the content ratio of the vinyl monomer a2 in the polymer A exceeds the upper limit of the aforementioned range, the compatibility of the polymer A with the polymer B described hereinafter decreases, and the colored portion formed using the color filter ink may be difficult to endow with adequate transparency. When the polymer A is a mixture of a plurality of types of compounds, the weighted average value (weighted average value based on weight ratio) of the mixed compounds may be used as the content ratio of the vinyl monomer a2. When the polymer A is a mixture of a plurality of types of compounds, the compounds all preferably contain the vinyl monomer a2 in such a content ratio as described above.

### Vinyl Monomer a3

The polymer A may contain at least the epoxy-containing vinyl monomer a1 as a monomer component, but the polymer A is preferably one (a copolymer) containing the epoxy-containing vinyl monomer a1, as well as a vinyl monomer a3 provided with a hydroxyl group. The colored portion formed using the color filter ink can thereby be endowed with particularly excellent adhesion to the substrate, particularly adhesion when repeatedly exposed to sudden temperature changes that accompany image display. As a result, the occurrence of light leakage (white spots, bright points) and other problems can be reliably prevented even when the color filter is used for a long time, for example. Specifically, the color filter can be endowed with particularly excellent durability. When the polymer A contains the vinyl monomer a3 as a monomer component, the polymer A can be endowed with particularly excellent compatibility with the polymer B described hereinafter, and the colored portion formed using the color filter ink can be endowed with extremely high transparency.

Examples of the vinyl monomer a3 include monoester compounds of a acrylic acid or methacrylic acid with 2-hydroxyethyl(meth)acrylate, hydroxypropyl(meth)acrylate, 2,3-dihydroxybutyl(meth)acrylate, 4-hydroxybutyl(meth)acrylate, 6-hydroxyhexyl(meth)acrylate, 8-hydroxyoctyl(meth)acrylate, 4-hydroxymethyl cyclohexyl(meth)acrylate, polyalkylene glycol mono(meth)acrylate, and other polyvalent alcohols; compounds in which 6-caprolactone is ring-open polymerized with the abovementioned monoester compounds of a polyvalent alcohol and acrylic acid or methacrylic acid (PLACCEL FA series, PLACCEL FM series, and the like manufactured by Daicel Chemical Industries); compounds in which ethylene oxide and propylene oxide is ring-open polymerized; and the like, and one or more types of compounds selected from the above examples may be used.

The content ratio (which is a value obtained by substitution with the weight of the monomer used to synthesize the polymer) of the vinyl monomer a3 in the polymer A is preferably 2 to 20 parts by weight, and more preferably 3 to 15 parts by weight, with respect to 100 parts by weight of the epoxy-containing vinyl monomer a1. When the content ratio of the vinyl monomer a3 in the polymer A is within the aforementioned range, the color filter manufactured using the color filter ink can be endowed with particularly excellent durability while the color filter ink is endowed with adequately excellent long-term storage properties and other characteristics. The colored portion formed using the color filter ink can also be endowed with high transparency. In contrast, when the content ratio of the vinyl monomer a3 in the polymer A is less than the lower limit of the aforementioned range, the effects of including a vinyl monomer a3 such as those described above may not be adequately demonstrated. When the content ratio of the vinyl monomer a3 in the polymer A exceeds the upper limit of the aforementioned range, it may be difficult to make the content ratio of gas in the color filter ink adequately low. When the polymer A is a mixture of a plurality of types of compounds, the weighted average value (weighted average value based on weight ratio) of the mixed compounds may be used as the content ratio of the vinyl monomer a3. When the polymer A is a mixture of a plurality of types of compounds, the compounds all preferably contain the vinyl monomer a3 in such a content ratio as described above.

### Other Polymerizable Vinyl Monomer a4

The polymer A may contain as a monomer component a polymerizable vinyl monomer a4 other than the epoxy-containing vinyl monomer a1, the vinyl monomer a2, and the vinyl monomer a3 described above. A vinyl monomer that can be copolymerized with the epoxy-containing vinyl monomer a1 may be used as the polymerizable vinyl monomer a4, and specific examples thereof include methyl(meth)acrylate, ethyl(meth)acrylate, butyl(meth)acrylate, 2-ethylhexyl(meth)acrylate, phenyl(meth)acrylate, cyclohexyl(meth)acrylate, dicyclopentanyl(meth)acrylate, dicyclopentanyloxyethyl(meth)acrylate, isobornyl(meth)acrylate, benzyl(meth)acrylate, phenylethyl(meth)acrylate, and other C₁₋₁₂ alkyl and aralkyl(meth)acrylates; styrene, α-methylstyrene, and other vinyl aromatic compounds, and one or more types of compounds selected from the above examples may be combined and used. However, the polymer A does not contain as a monomer component a fluoroalkyl- or fluoroaryl-containing vinyl monomer b1 such as described hereinafter. The polymer A also preferably does not contain an alkoxysilyl-containing vinyl monomer such as described above as a monomer component.

The content ratio (which is a value obtained by substitution with the weight of the monomer used to synthesize the polymer) of the polymerizable vinyl monomer a4 in the polymer A is preferably 15 parts by weight or less, and more preferably 7 parts by weight or less with respect to 100 parts by weight of the epoxy-containing vinyl monomer a1. When the polymer A is a mixture of a plurality of types of compounds, the weighted average value (weighted average value based on weight ratio) of the mixed compounds may be used as the content ratio of the polymerizable vinyl monomer a4. When the polymer A is a mixture of a plurality of types of compounds, the content ratio of the polymerizable vinyl monomer a4 with respect to the mixture of compounds preferably satisfies such conditions as those described above.

As described above, the polymer A may contain at least the epoxy-containing vinyl monomer a1 as a monomer component, and does not contain the fluoroalkyl- or fluoroaryl-containing vinyl monomer b1 described hereinafter as a monomer component, but preferably contains the epoxy-containing vinyl monomer a1 as well as the vinyl monomer a2 and the vinyl monomer a3. The effects of including a vinyl monomer a2 such as the ones described above, and the effects of including a vinyl monomer a3 such as the ones described above can be obtained at the same time.

The ratio (content ratio) accounted for by the polymer A in the resin material (binder resin) is not particularly limited, but is preferably 25 to 80 wt %, and more preferably 33 to 70 wt %. When the polymer A is a mixture of a plurality of types of compounds, the sum of the content ratios of the mixed compounds may be used as the content ratio of the polymer A.

### Polymer B

In the color filter ink of the present invention, the resin material (binder resin) includes a polymer A such as described above, as well as a polymer B that contains at least the fluoroalkyl- or fluoroaryl-containing vinyl monomer b1 indicated by Formula (1) below as a monomer component.

Formula (1)

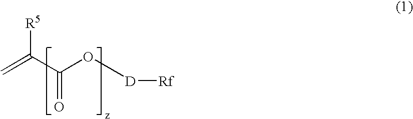

In Formula (1), R⁵ is a hydrogen atom or a C₁₋₇ alkyl group; D is a single bond hydrocarbon group or a bivalent hydrocarbon group optionally including a hetero atom; Rf is a C₁₋₂₀ fluoroalkyl group or fluoroaryl group; and z is 0 or 1.

In the conventional color filter ink, it is usually the case that relatively large amounts of gas are easily incorporated during preparation of the ink, and even when de-aeration or the like is performed, the gas content is difficult to reduce. Even once the gas content in the conventional color filter ink is reduced to a relatively low level by de-aeration or the like, gas from the atmosphere is incorporated over the course of prolonged storage, and when discharge, fluid depletion, and the like of ink from the discharge holes during droplet discharge are repeated, gas from the atmosphere is incorporated, thereby resulting in a strong tendency for the content ratio of gas (dissolved gas, bubbles present as microbubbles, or the like) in the color filter ink to increase. When the gas content ratio in the color filter ink increases in this manner, the discharge of droplets by the inkjet method becomes unstable, and unevenness of color and saturation between regions, and fluctuation of characteristics between individual units easily occur.

In the present invention, however, the resin material (binder resin) includes the polymer A as well as the polymer B, whereby the content ratio of gas in the color filter ink can be reduced, the color filter ink can be endowed with excellent discharge stability, the color filter manufactured using the color filter ink can be endowed with excellent uniformity of characteristics between individual units, and unevenness of color saturation between different regions can be suppressed. By including the polymer A as well as the polymer B in the resin material (binder resin), the color filter manufactured using the color filter ink can be endowed with excellent durability. By including the polymer A as well as the polymer B in the resin material (binder resin) in the present invention, excellent mixing stability of the resin material with the colorant (pigment) can be obtained over a long period of time, and a color filter having excellent contrast can be manufactured stably over a long period of time. Since the color filter ink, once prepared, can be suitably used for a long time, the frequency of replacing the color filter ink and replacing the color filter ink in the droplet discharge device can be reduced. The color filter can therefore be manufactured with particularly excellent productivity, and the consistency of quality of the manufactured color filter is enhanced. Such excellent effects (synergistic effects) are not obtained with only one of the polymer A or polymer B is used.

The polymer B may be composed of essentially a single compound, or may be a mixture of a plurality of types of compounds. However, when the polymer B is a mixture of a plurality of types of compounds, each of the compounds contains at least the fluoroalkyl- or fluoroaryl-containing vinyl monomer b1 as a monomer component.

### Fluoroalkyl- or Fluoroaryl-Containing Vinyl Monomer b1

The polymer B contains at least the fluoroalkyl- or fluoroaryl-containing vinyl monomer b1 indicated by Formula (1) as a monomer component. Including such a fluoroalkyl- or fluoroaryl-containing vinyl monomer b1 as a monomer component makes it possible to easily and reliably introduce a fluoroalkyl group or a fluoroaryl group into the polymer B. By including the fluoroalkyl- or fluoroaryl-containing vinyl monomer b1 as a monomer component, unwanted adhesion of droplets to the nozzles of the droplet discharge device, and adhesion (bonding) of solid components of the color filter ink to the nozzles can be more reliably prevented, and excellent discharge stability of droplets can be maintained over a long period of time. By including the fluoroalkyl- or fluoroaryl-containing vinyl monomer b1 as a monomer component, the formed colored portion can be endowed with adequately excellent hardness, adhesion to the substrate, light fastness, thermal resistance, and other characteristics. When the polymer B includes a vinyl monomer b2 or the like such as described hereinafter, the polymer can be suitably synthesized, and a polymer B having the desired characteristics can be easily and reliably obtained.

In Formula (1), examples of the C₁₋₇ alkyl group indicated by R⁵ include methyl, ethyl, propyl, isopropyl, butyl, isobutyl, s-butyl, pentyl, hexyl, heptyl, and other alkyl groups, but a hydrogen atom or a C₁₋₂ alkyl group is preferred, and a hydrogen atom or a methyl group is more preferred. The color filter ink can thereby be endowed with particularly excellent discharge stability, and the colored portion formed using the color filter ink can be endowed with particularly excellent thermal resistance.

Typical examples of the bivalent hydrocarbon group (hydrocarbon group optionally including a hetero atom) indicated by D in Formula (1) include straight-chain or branched alkylene groups, or more specifically, methylenes, ethylenes, propylenes, tetramethylenes, ethyl ethylenes, pentamethylenes, hexamethylenes, oxymethylenes, oxyethylenes, oxypropylenes, and the like.

Specific examples of monomers indicated by Formula (1) include CF₃(CF₂)₃CH₂CH═CH₂, CF₃(CF₂)₃CH═CH₂, CF₃(CF₂)₅CH₂CH═CH₂, CF₃(CF₂)₅CH═CH₂, CF₃(CF₂)₇CH═CH₂, CF₃(CF₂)₉CH₂CH═CH₂, CF₃(CF₂)₉CH═CH₂, (CF₃)₂CF(CF₂)₂CH₂CH═CH₂, (CF₃)₂CF(CF₂)₂CH═CH₂, (CF₃)₂CF(CF₂)₄CH₂CH═CH₂, (CF₃)₂CF(CF₂)₄CH═CH₂, (CF₃)₂CF(CF₂)₆CH₂CH═CH₂, (CF₃)₂CF(CF₂)₆CH═CH₂, F₅C₆CH═CH₂, CF₃(CF₂)₅CH₂CH₂OCH₂CH═CH₂, CF₃(CF₂)₅CH₂CH₂CH₂OCH₂CH═CH₂, CF₃(CF₂)₇CH₂CH₂OCH₂CH═CH₂, CF₃(CF₂)₇CH₂CH₂CH₂OCH₂CH═CH₂, CF₃(CF₂)₉CH₂CH₂OCH₂CH═CH₂, CF₃(CF₂)₉CH₂CH₂CH₂OCH₂CH═CH₂, H(CF₂)₆CH₂OCH₂CH═CH₂, H(CF₂)₈CH₂OCH₂CH═CH₂, (CF₃)₂CF(CF₂)₂CH₂CH₂OCOCH═CH₂, (CF₃)₂CF(CF₂)₂CH₂CH₂OCOC(CH₃)═CH₂, (CF₃)₂CF(CF₂)₄CH₂CH₂OCOCH═CH₂, (CF₃)₂CF(CF₂)₄CH₂CH₂OCOC(CH₃)═CH₂, (CF₃)₂CF(CF₂)₆CH₂CH₂OCOCH═CH₂, (CF₃)₂CF(CF₂)₆CH₂CH₂OCOC(CH₃)═CH₂, CF₃(CF₂)₅CH₂CH₂OCOCH═CH₂, CF₃(CF₂)₅CH₂CH₂OCOC(CH₃)═CH₂, CF₃(CF₂)₇CH₂CH₂OCOCH═CH₂, CF₃(CF₂)₇CH₂CH₂OCOC(CH₃)═CH₂, CF₃(CF₂)₉CH₂CH₂OCOCH═CH₂, CF₃(CF₂)₉CH₂CH₂OCOC(CH₃)═CH₂, H(CF₂)₆CH₂CH₂OCOCH═CH₂, H(CF₂)₈CH₂CH₂OCOC(CH₃)═CH₂, F(CF₂)₈CH₂CH₂OCOCH═CH₂, F(CF₂)₈CH₂CH₂OCOC(CH₃)═CH₂, H(CF₂)₄CH₂OCOC(CH₃)═CH₂, H(CF₂)₄CH₂OCOCH═CH₂, and the like, and one or more types of compounds selected from the above examples may be combined and used.

The content ratio (which is a value obtained by substitution with the weight of the monomer used to synthesize the polymer) of the fluoroalkyl- or fluoroaryl-containing vinyl monomer b1 in the polymer B is preferably 10 to 60 wt %, and more preferably 15 to 50 wt %. When the content ratio of the fluoroalkyl- or fluoroaryl-containing vinyl monomer b1 in the polymer B is within the aforementioned range, the discharge stability of the color filter ink and the thermal resistance of the colored portion formed using the color filter ink can be made particularly excellent. The compatibility of the polymer B with respect to the polymer A can also be made particularly excellent, and the colored portion formed using the color filter ink can be endowed with particularly high transparency. In contrast, when the content ratio of the fluoroalkyl- or fluoroaryl-containing vinyl monomer b1 in the polymer B is less than the aforementioned lower limit, the effects of including the fluoroalkyl- or fluoroaryl-containing vinyl monomer b1 such as described above may not be adequately demonstrated. When the content ratio of the fluoroalkyl- or fluoroaryl-containing vinyl monomer b1 in the polymer B exceeds the aforementioned upper limit, it may be difficult to endow the colored portion formed using the color filter ink with adequately excellent transparency. When the polymer B is a mixture of a plurality of types of compounds, the weighted average value (weighted average value based on weight ratio) of the mixed compounds may be used as the content ratio of the fluoroalkyl- or fluoroaryl-containing vinyl monomer b1. When the polymer B is a mixture of a plurality of types of compounds, the compounds all preferably contain the fluoroalkyl- or fluoroaryl-containing vinyl monomer b1 in such a content ratio as described above.

### Other Polymerizable Vinyl Monomer b2

The polymer B may contain as a monomer component a polymerizable vinyl monomer b2 other than the fluoroalkyl- or fluoroaryl-containing vinyl monomer b1 such as described above. A vinyl monomer that can be copolymerized with the fluoroalkyl- or fluoroaryl-containing vinyl monomer b1 may be used as the polymerizable vinyl monomer b2, and specific examples thereof include glycidyl(meth)acrylate, methylglycidyl(meth)acrylate, ethylglycidyl(meth)acrylate, glycidyl vinylbenzyl ether (product name: VBGE; manufactured by Seimi Chemical), and epoxy-containing vinyl monomers indicated by Formula (2) above such as the alicyclic epoxy-containing unsaturated compounds indicated by Formulas (2-1) through (2-31) above; 2-acryloyloxyethyl isocyanate (product name: Karenz MOI; manufactured by Showa Denko), 2-methacryloyloxyethyl isocyanate, and other (meth)acryloyl isocyanates and the like in which (meth)acryloyl is bonded with an isocyanate group via a C₂₋₆ alkylene group; ethyl 2-(0-[1′-methylpropylideneamino]carboxyamino)methacrylate (product name: Karenz MOI-BM; manufactured by Showa Denko) and other polymerizable vinyl monomers provided with an isocyanate group or a block isocyanate group in which an isocyanate group is protected by a protective group; 2-hydroxyethyl(meth)acrylate, hydroxypropyl(meth)acrylate, 2,3-dihydroxybutyl(meth)acrylate, 4-hydroxybutyl(meth)acrylate, 6-hydroxyhexyl(meth)acrylate, 8-hydroxyoctyl(meth)acrylate, 4-hydroxymethyl cyclohexyl(meth)acrylate, polyalkylene glycol mono(meth)acrylate, and other monoester compounds of a polyvalent alcohol and acrylic acid or methacrylic acid; compounds in which ε-caprolactone is ring-open polymerized with the abovementioned monoester compounds of a polyvalent alcohol and acrylic acid or methacrylic acid (PLACCEL FA series, PLACCEL FM series, and the like manufactured by Daicel Chemical Industries); compounds in which ethylene oxide and propylene oxide is ring-open polymerized, and other polymerizable vinyl monomers provided with a hydroxyl group; methyl(meth)acrylate, ethyl(meth)acrylate, butyl(meth)acrylate, 2-ethylhexyl(meth)acrylate, phenyl(meth)acrylate, cyclohexyl(meth)acrylate, dicyclopentanyl(meth)acrylate, dicyclopentanyloxyethyl(meth)acrylate, isobornyl(meth)acrylate, benzyl(meth)acrylate, phenylethyl(meth)acrylate, and other C₁₋₁₂ alkyl and aralkyl(meth)acrylates; styrene, α-methylstyrene, and other vinyl aromatic compounds; vinyltrimethoxysilane, vinyltriethoxysilane, vinylmethyldimethoxysilane, vinylmethyldiethoxysilane, γ-(meth)acryloyloxypropyltrimethoxysilane, γ-(meth)acryloyloxypropylmethyldimethoxysilane, γ-(meth)acryloyloxypropylmethyldiethoxysilane, γ-(meth)acryloyloxypropyltriethoxysilane, β-(meth)acryloyloxyethyltrimethoxysilane, γ-(meth)acryloyloxybutylphenyldimethoxysilane, and other alkoxysilyl-containing vinyl monomers and the like, and one or more types of compounds selected from the above examples may be combined and used. Among these examples, including an epoxy-containing vinyl monomer as the polymerizable vinyl monomer b2 makes it possible to obtain particularly excellent compatibility between the polymer A and the polymer B, and to endow the colored portion formed using the color filter ink with extremely excellent transparency. However, the polymer B preferably does not include an alkoxysilyl-containing vinyl monomer such as described hereinafter as a monomer component.

The content ratio (which is a value obtained by substitution with the weight of the monomer used to synthesize the polymer) of the polymerizable vinyl monomer b2 in the polymer B is preferably 40 to 90 wt %, and more preferably 50 to 85 wt %. When the polymer B is a mixture of a plurality of types of compounds, the weighted average value (weighted average value based on weight ratio) of the mixed compounds may be used as the content ratio of the polymerizable vinyl monomer b2. When the polymer B is a mixture of a plurality of types of compounds, the content ratio of the polymerizable vinyl monomer b2 with respect to the mixture of compounds preferably satisfies such conditions as those described above.

The ratio (content ratio) accounted for by the polymer B in the resin material (binder resin) is not particularly limited, but is preferably 20 to 60 wt %, and more preferably 25 to 55 wt %. When the polymer B is a mixture of a plurality of types of compounds, the sum of the content ratios of the mixed compounds may be used as the content ratio of the polymer B.

The ratio of the polymer A content and the polymer B content in terms of weight is preferably 25:75 to 75:25, and more preferably 45:55 to 55:45. Satisfying such conditions enables the color filter ink to be endowed with particularly excellent discharge stability. The color filter manufactured using the color filter ink can be endowed with excellent uniformity of characteristics between individual units, and unevenness of color and saturation between different regions can be more reliably prevented. The color filter can also be endowed with excellent durability.

### Polymer C

The resin material (binder resin) includes the polymer A and polymer B such as described above, but also may include a polymer C that contains as a monomer component the alkoxysilyl-containing vinyl monomer c1 indicated by Formula (3) below.

Formula (3)

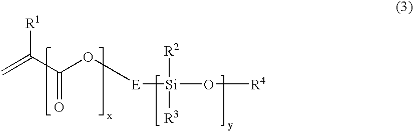

In Formula (3), R¹ is a hydrogen atom or a C₁₋₇ alkyl group; E is a single bond hydrocarbon group or a bivalent hydrocarbon group; R² and R³ are the same or different C₁₋₆ alkyl groups or C₁₋₆ alkoxyl groups; R⁴ is a C₁₋₆ alkyl group; x is 0 or 1; and y is an integer from 1 to 10.

By including such a polymer C, curing of the polymer A can be supplemented when the resin material (curable resin material) is cured to form the colored portion, the colored portion can be formed under relatively mild conditions, and the formed colored portion can be endowed with particularly excellent hardness, adhesion to the substrate, and other characteristics.

The polymer C may be composed of essentially a single compound, or may be a mixture of a plurality of types of compounds. However, when the polymer C is a mixture of a plurality of types of compounds, each of the compounds contains at least the alkoxysilyl-containing vinyl monomer c1 as a monomer component.

### Alkoxysilyl-Containing Vinyl Monomer c1

The polymer C contains at least the alkoxysilyl-containing vinyl monomer c1 indicated by Formula (3) as a monomer component. Including such an alkoxysilyl-containing vinyl monomer c1 as a monomer component makes it possible to easily and reliably introduce an alkoxysilyl group into the polymer C. By including the alkoxysilyl-containing vinyl monomer c1 as a monomer component, curing of the polymer A can be supplemented when the resin material (curable resin material) is cured to form the colored portion, the colored portion can be formed under relatively mild conditions, and the formed colored portion can be endowed with particularly excellent hardness, adhesion to the substrate, and other characteristics. When the polymer C includes a vinyl monomer c2 or the like such as described hereinafter, the polymer can be suitably synthesized, and a polymer C having the desired characteristics can be easily and reliably obtained.

In Formula (3), examples of the C₁₋₇ alkyl group indicated by R¹ include methyl, ethyl, propyl, isopropyl, butyl, isobutyl, s-butyl, pentyl, hexyl, heptyl, and other alkyl groups, but a hydrogen atom or a C₁₋₂ alkyl group is preferred, and a hydrogen atom or a methyl group is more preferred. The color filter ink can thereby be endowed with particularly excellent discharge stability, and the formed colored portion can be endowed with particularly excellent hardness, adhesion to the substrate, and other characteristics. The polymer C can also be endowed with particularly excellent compatibility with the polymer A, and the colored portion formed using the color filter ink can be endowed with particularly high transparency.

Typical examples of the bivalent hydrocarbon group indicated by E in Formula (3) include straight-chain or branched alkylene groups, or more specifically, methylenes, ethylenes, propylenes, tetramethylenes, ethyl ethylenes, pentamethylenes, hexamethylenes, and the like. Among these examples, a C₁₋₃ straight-chain alkylene group (e.g., methylene, ethylene, propylene) is particularly preferred.

Examples of the C₁₋₆ alkyl groups indicated by R², R³, and R⁴ in Formula (3) include straight-chain or branched alkyl groups, e.g., methyl, ethyl, propyl, isopropyl, butyl, isobutyl, s-butyl, pentyl, hexyl, and the like. Examples of the C₁₋₆ alkoxyl groups indicated by R² and R³ include straight-chain or branched alkoxyl groups, e.g., methoxy, ethoxy, propoxy, isopropoxy, butoxy, isobutoxy, s-butoxy, pentoxy, hexyloxy, and the like.

Specific examples of monomers indicated by Formula (3) include vinyltrimethoxysilane, vinyltriethoxysilane, vinylmethyldimethoxysilane, vinylmethyldiethoxysilane, γ-(meth)acryloyloxypropyltrimethoxysilane, γ-(meth)acryloyloxypropylmethyldimethoxysilane, γ-(meth)acryloyloxypropylmethyldiethoxysilane, γ-(meth)acryloyloxypropyltriethoxysilane, β-(meth)acryloyloxyethyltrimethoxysilane, γ-(meth)acryloyloxybutylphenyldimethoxysilane, and other alkoxysilyl-containing polymerizable unsaturated compounds and the like, and one or more types of compounds selected from the above examples may be combined and used.

The content ratio (which is a value obtained by substitution with the weight of the monomer used to synthesize the polymer) of the alkoxysilyl-containing vinyl monomer c1 in the polymer C is preferably 70 to 100 wt %, and more preferably 80 to 100 wt %. When the content ratio of the alkoxysilyl-containing vinyl monomer c1 in the polymer C is within the aforementioned range, the color filter ink can be endowed with particularly excellent discharge stability, curing of the polymer A can be supplemented when the resin material (curable resin material) is cured to form the colored portion, and the colored portion can be formed under relatively mild conditions. The formed colored portion can also be endowed with particularly excellent hardness, adhesion to the substrate, and other characteristics. When the polymer C is a mixture of a plurality of types of compounds, the weighted average value (weighted average value based on weight ratio) of the mixed compounds may be used as the content ratio of the alkoxysilyl-containing vinyl monomer c1. When the polymer C is a mixture of a plurality of types of compounds, the compounds all preferably contain the alkoxysilyl-containing vinyl monomer c1 in such a content ratio as described above.

### Other Polymerizable Vinyl Monomer c2

The polymer C may contain at least the alkoxysilyl-containing vinyl monomer c1 as a monomer component, but may also contain as a monomer component a polymerizable vinyl monomer c2 other than the alkoxysilyl-containing vinyl monomer c1, in addition to the alkoxysilyl-containing vinyl monomer c1. A vinyl monomer that can be copolymerized with the alkoxysilyl-containing vinyl monomer c1 may be used as the polymerizable vinyl monomer c2, and specific examples thereof include 2-hydroxyethyl(meth)acrylate, hydroxypropyl(meth)acrylate, 2,3-dihydroxybutyl(meth)acrylate, 4-hydroxybutyl(meth)acrylate, 6-hydroxyhexyl(meth)acrylate, 8-hydroxyoctyl(meth)acrylate, 4-hydroxymethyl cyclohexyl(meth)acrylate, polyalkylene glycol mono(meth)acrylate, and other monoester compounds of a polyvalent alcohol and acrylic acid or methacrylic acid; compounds in which ε-caprolactone is ring-open polymerized with the abovementioned monoester compounds of a polyvalent alcohol and acrylic acid or methacrylic acid (PLACCEL FA series, PLACCEL FM series, and the like manufactured by Daicel Chemical Industries); compounds in which ethylene oxide and propylene oxide is ring-open polymerized, and other polymerizable vinyl monomers provided with a hydroxyl group; methyl(meth)acrylate, ethyl(meth)acrylate, butyl(meth)acrylate, 2-ethylhexyl(meth)acrylate, phenyl(meth)acrylate, cyclohexyl(meth)acrylate, dicyclopentanyl(meth)acrylate, dicyclopentanyloxyethyl(meth)acrylate, isobornyl(meth)acrylate, benzyl(meth)acrylate, phenylethyl(meth)acrylate, and other C₁₋₁₂ alkyl and aralkyl(meth)acrylates; styrene, α-methylstyrene, and other vinyl aromatic compounds and the like, and one or more types of compounds selected from the above examples may be combined and used. However, the polymer C does not contain as monomer components an epoxy-containing vinyl monomer a1 and a fluoroalkyl- or fluoroaryl-containing vinyl monomer b1 such as previously described.

The content ratio (which is a value obtained by substitution with the weight of the monomer used to synthesize the polymer) of the polymerizable vinyl monomer c2 in the polymer C is preferably 30 wt % or less, and more preferably 20 wt % or less. When the polymer C is a mixture of a plurality of types of compounds, the weighted average value (weighted average value based on weight ratio) of the mixed compounds may be used as the content ratio of the polymerizable vinyl monomer c2. When the polymer C is a mixture of a plurality of types of compounds, the content ratio of the polymerizable vinyl monomer c2 with respect to the mixture of compounds preferably satisfies such conditions as those described above.

As described above, the polymer C may contain at least the alkoxysilyl-containing vinyl monomer c1 as a monomer component, and may contain a monomer component other than the alkoxysilyl-containing vinyl monomer c1, but is preferably a homopolymer of the alkoxysilyl-containing vinyl monomer c1. Specifically, the polymer C preferably does not contain components other than the alkoxysilyl-containing vinyl monomer c1 as monomer components. The discharge stability of the color filter ink and the durability (particularly adhesion to the substrate) of the color filter manufactured using the color filter ink can thereby be made particularly excellent.

The ratio (content ratio) accounted for by the polymer C in the resin material (binder resin) is not particularly limited, but is preferably 20 to 60 wt %, and more preferably 25 to 55 wt %. When the polymer C is a mixture of a plurality of types of compounds, the sum of the content ratios of the mixed compounds may be used as the content ratio of the polymer C.

The ratio of the polymer A content and the polymer C content in terms of weight is preferably 25:75 to 75:25, and more preferably 45:55 to 55:45. Satisfying such conditions enables the color filter ink to be endowed with particularly excellent discharge stability. The color filter manufactured using the color filter ink can be endowed with excellent uniformity of characteristics between individual units, and unevenness of color and saturation between different regions can be more reliably prevented. The color filter can also be endowed with particularly excellent durability.

The weight-average molecular weight of each polymer (polymer A, polymer B, polymer C) such as described above is preferably 1000 to 50000, more preferably 1200 to 10000, and even more preferably 1500 to 5000. The degree of dispersion (weight-average molecular weight Mw/number-average molecular weight Mn) of each polymer (polymer A, polymer B, polymer C) such as described above is about 1 to 3.

The content ratio of the resin material in the color filter ink is preferably 0.5 to 10 wt %, and more preferably 1 to 5 wt %. When the content ratio of the resin material is within this range, the manufactured color filter can be endowed with particularly excellent durability while providing the color filter ink with excellent discharge properties from the droplet discharge head. Adequate color saturation can also be maintained in the manufactured color filter.

The resin material (binder resin) constituting the color filter ink may also include a polymer other than the polymer A, polymer B, and polymer C described above.

### Liquid Medium

The liquid medium (liquid vehicle) has the function of dissolving and/or dispersing the colorant and other components such as described above. Specifically, the liquid medium functions as a solvent and/or dispersion medium. Most of the liquid medium is usually removed in the process of manufacturing the color filter.

Ester compounds, ether compounds, hydroxyketones, carbonic diesters, cyclic amides, and the like may be used as the liquid medium constituting the color filter ink, preferred among which are (1) ethers (polyvalent alcohol ethers) as condensates of polyvalent alcohols (e.g., ethylene glycol, propylene glycol, butylene glycol, glycerin, and the like); alkyl ethers (e.g., methyl ether, ethyl ether, butyl ether, hexyl ether, and the like) of polyvalent alcohols or polyvalent alcohol ethers; and esters (e.g., formate, acetate, propionate, and the like); (2) esters (e.g., methyl esters and the like) of polyvalent carboxylic acids (e.g., succinic acid, glutamic acid, and the like); (3) ethers, esters, and the like of compounds (hydroxy acids) having at least one hydroxyl group and at least one carboxyl group in the molecule thereof; and (4) carbonic diesters having a chemical structure such as that obtained by reaction of a polyvalent alcohol and a phosgene. Examples of compounds that can be used as the liquid medium include 2-(2-methoxy-1-methylethoxy)-1-methyl ethyl acetate, triethylene glycol dimethyl ether, triethylene glycol diacetate, diethylene glycol monoethyl ether acetate, 4-methyl-1,3-dioxolan-2-one, bis(2-butoxyethyl)ether, dimethyl glutarate, ethylene glycol di-n-butyrate, 1,3-butylene glycol diacetate, diethylene glycol monobutyl ether acetate, tetraethylene glycol dimethyl ether, 1,6-diacetoxyhexane, tripropylene glycol monomethyl ether, butoxypropanol, diethylene glycol methylethyl ether, diethylene glycol methyl butyl ether, triethylene glycol methylethyl ether, triethylene glycol methyl butyl ether, dipropylene glycol monomethyl ether acetate, diethylene glycol dimethyl ether, ethyl 3-ethoxy propionate, diethylene glycol ethyl methyl ether, 3-methoxybutyl acetate, diethylene glycol diethyl ether, ethyl octanoate, ethylene glycol monobutyl ether acetate, ethylene glycol monobutyl ether, cyclohexyl acetate, diethyl succinate, ethylene glycol diacetate, propylene glycol diacetate, 4-hydroxy-4-methyl-2-pentanone, dimethyl succinate, 1-butoxy-2-propanol, diethylene glycol monoethyl ether, diethylene glycol monomethyl ether, dipropylene glycol monomethyl ether, 3-methoxy-n-butyl acetate, diacetin, dipropylene glycol mono n-propyl ether, polyethylene glycol monomethyl ether, butyl glycolate, ethylene glycol monohexyl ether, dipropylene glycol mono n-butyl ether, N-methyl-2-pyrrolidone, triethylene glycol butyl methyl ether, bis(2-propoxyethyl)ether, diethylene glycol diacetate, diethylene glycol butyl methyl ether, diethylene glycol butyl ethyl ether, diethylene glycol butyl propyl ether, diethylene glycol ethyl propyl ether, diethylene glycol methyl propyl ether, diethylene glycol propyl ether acetate, triethylene glycol methyl ether acetate, triethylene glycol ethyl ether acetate, triethylene glycol propyl ether acetate, triethylene glycol butyl ether acetate, triethylene glycol butyl ethyl ether, triethylene glycol ethyl methyl ether, triethylene glycol ethyl propyl ether, triethylene glycol methyl propyl ether, dipropylene glycol methyl ether acetate, n-nonyl alcohol, diethylene glycol monobutyl ether, triethylene glycol monomethyl ether, ethylene glycol 2-ethylhexyl ether, triethylene glycol monoethyl ether, diethylene glycol monohexyl ether, triethylene glycol monobutyl ether, diethylene glycol mono-2-ethylhexyl ether, tripropylene glycol mono n-butyl ether, butyl cellosolve acetate, and the like, and one or more types of compounds selected from the above examples may be combined and used.

Among these examples, when a mixture of 1,3-butylene glycol diacetate and diethylene glycol monobutyl ether acetate is used as the liquid medium, the color filter ink can be endowed with particularly excellent discharge stability of droplets; unevenness of color, saturation, and the like in regions of the manufactured color filter can be more effectively suppressed, and the color filter can be endowed with particularly excellent uniformity of characteristics between individual units. Particularly when the color filter ink includes a pigment as the colorant, because of the chemical structural interaction between the aforementioned compounds and the resin material such as previously described, the resin material can be unevenly distributed on the surfaces of the pigment particles in the color filter ink, particularly excellent discharge stability of droplets can be obtained, the dispersion stability of the pigment particles in the color filter ink can be made particularly excellent, and the color filter ink can be endowed with particularly excellent long-term storage properties while the dissolving properties of the resin material such as previously described are made adequately excellent. When a mixture of 1,3-butylene glycol diacetate and diethylene glycol monobutyl ether acetate is used as the liquid medium, the color filter ink can be reliably made to spread into the entire cell in the method for manufacturing a color filter such as previously described, and a flattened colored portion can easily be formed even when the conditions for removing the liquid medium are not strictly prescribed. In other words, the internal shape of the pixels is easily controlled during baking.

When a mixture of 1,3-butylene glycol diacetate and diethylene glycol monobutyl ether acetate is used as the liquid medium, the mixture ratio of the 1,3-butylene glycol diacetate and diethylene glycol monobutyl ether acetate in terms of weight is preferably 75:25 to 98:2, and more preferably 80:20 to 95:5. Such effects as those described above are thereby more significantly demonstrated.

Among examples (1) through (4) above, (1) is preferred, and a compound having a propylene glycol backbone and alkoxy groups at both terminal ends thereof is more preferred. Through the use of such a compound, the color filter ink can be endowed with particularly excellent discharge stability of droplets; unevenness of color, saturation, and the like in regions of the manufactured color filter can be more effectively suppressed, and the color filter can be endowed with particularly excellent uniformity of characteristics between individual units. Particularly when the color filter ink includes a pigment as the colorant, because of the chemical structural interaction between the aforementioned compounds and the resin material such as previously described, the resin material can be unevenly distributed on the surfaces of the pigment particles in the color filter ink, particularly excellent discharge stability of droplets can be obtained, the dispersion stability of the pigment particles in the color filter ink can be made particularly excellent, and the color filter ink can be endowed with particularly excellent long-term storage properties while the dissolving properties of the resin material such as previously described are made adequately excellent. The color filter can also be manufactured with particularly excellent productivity. The color filter can also be endowed with particularly excellent durability. Even when the content ratio of the pigment in the color filter ink is relatively high, the dispersion stability of the pigment can be adequately excellent, and the color filter ink can be endowed with excellent stability (long-term storage properties). Including a compound having a propylene glycol backbone and alkoxy groups at both terminal ends thereof as the liquid medium makes it possible to effectively prevent degradation of the droplet discharge head used for droplet discharge. The frequency of replacement, repair, and other maintenance of the droplet discharge head can therefore be reduced even when a large number of color filters are manufactured, and the color filter can be manufactured with excellent productivity.

The compound (compound having a propylene glycol backbone and alkoxy groups at both terminal ends thereof) having the chemical structure such as described above can be indicated by the general formula (4) below.

Formula (4)

RO[(CH₂CH(CH₃)O)ₗ(CH(CH₃)CH₂O)ₘ(CH₂CH₂CH₂O)ₙ]R′ (4)

In Formula (4), R and R′ are each independently an alkyl group having a carbon number of 1 or higher; l, m, and n are integers 0 or higher; and l+m+n is 1 or higher.

Specific examples of R and R′ in Formula (4) include such groups as the following: methyl (CH₃), ethyl (CH₃CH₂), propyl (CH₃CH₂CH₂), isopropyl (CH₃CH(CH₃)), butyl (CH₃CH₂CH₂CH₂), isobutyl (CH₃CH(CH₃)CH₂), sec-butyl (CH₃CH₂CH(CH₃)), t-butyl ((CH₃)₃C), pentyl (CH₃CH₂CH₂CH₂CH₂), hexyl (CH₃CH₂CH₂CH₂CH₂), heptyl (CH₃CH₂CH₉CH?CH₂), and octyl (CH₃CH₂CH₂CH₂CH₂), but C₁₋₄ alkyl groups are preferred.

As described above, l+m+n may be an integer 1 or higher, but an integer 2 to 5 is preferred, and an integer 2 to 3 is more preferred. Such effects as those described above can thereby be more significantly demonstrated, the color filter ink can be endowed with particularly excellent discharge stability and long-term storage properties (storage stability), and the manufactured color filter can be endowed with particularly excellent durability. Unevenness of color, saturation, and the like in different regions of the color filter can also be more effectively suppressed, and particularly excellent uniformity of characteristics between individual units can be obtained.

Specific examples of compounds that can be used as the liquid medium that have a chemical structure such as described above include CH₃OCH₂CH(CH₃)OCH₃, CH₃O(CH₂CH(CH₃)O)₂CH₃, CH₃O(CH₂CH(CH₃)O)₃CH₃, CH₃O(CH₂CH(CH₃O)₄CH₃, CH₃O(CH₂CH(CH₃)O₅CH₃, CH₃OCH₂CH₂CH₂OCH₃, CH₃O(CH₂CH₂CH₂O)₂CH₃, CH₃O(CH₂CH₂CH₂O)₃CH₃, CH₃O(CH₂CH₂CH₂O)₄CH₃, CH₃O(CH₂CH₂CH₂O)₅CH₃, CH₃O[(CH₂CH(CH₃O)(CH(CH₃)CH₂O))CH₃, CH₃O[(CH₂CH(CH₃)O)(CH₂CH₂CH₂O)]CH₃, CH₃O[(CH₂CH(CH₃)O)(CH(CH₃)CH₂O)(CH₂CH₂CH₂O)]CH₃, CH₃CH₂OCH₂CH(CH₃)OCH₃, CH₃CH₂O(CH₂CH(CH₃)O)₂CH₃, CH₃CH₂O(CH₂CH(CH₃)O)₃CH₃, CH₃CH₂O(CH₂CH(CH₃)O₄CH₃, CH₃CH₂O(CH₂CH(CH₃)O₅CH₃, CH₃CH₂OCH(CH₃)CH₂OCH₃, CH₃CH₂O(CH(CH₃)CH₂O)₂CH₃, CH₃CH₂O(CH(CH₃)CH₂O)₃CH₃, CH₃CH₂O(CH(CH₃)CH₂O)₄CH₃, CH₃CH₂O(CH(CH₃)CH₂O)₅CH₃, CH₃CH₂OCH₂CH₂CH₂OCH₃, CH₃CH₂O(CH₂CH₂CH₂O)₂CH₃, CH₃CH₂O(CH₂CH₂CH₂O)₃CH₃, CH₃CH₂O(CH₂CH₂CH₂O)₄CH₃, CH₃CH₂O(CH₂CH₂CH₂O)₅CH₃, CH₃CH₂O[(CH₂CH(CH₃)O)(CH(CH₃)CH₂O)]CH₃, CH₃CH₂O[(CH₂CH(CH₃)O)(CH₂CH₂CH₂O)]CH₃, CH₃CH₂O[(CH₂CH(CH₃)O)(CH(CH₃)CH₂O)(CH₂CH₂CH₂O)]CH₃, CH₃CH₂OCH₂CH(CH₃)OCH₂CH₃, CH₃CH₂O(CH₂CH(CH₃)O)₂CH₂CH₃, CH₃CH₂O(CH₂CH(CH₃)O)₃CH₂CH₃, CH₃CH₂O(CH₂CH(CH₃)O)₄CH₂CH₃, CH₃CH₂O(CH₂CH(CH₃)O)₅CH₂CH₃, CH₃CH₂OCH₂CH₂CH₂OCH₂CH₃, CH₃CH₂O(CH₂CH₂CH₂O)₂CH₂CH₃, CH₃CH₂O(CH₂CH₂CH₂O)₃CH₂CH₃, CH₃CH₂O(CH₂CH₂CH₂O)₄CH₂CH₃, CH₃CH₂O(CH₂CH₂CH₂O)₅CH₂CH₃, CH₃CH₂O[(CH₂CH(CH₃)O)(CH(CH₃)CH₂O)]CH₂CH₃, CH₃CH₂O[(CH₂CH(CH₃)O)(CH₂CH₂CH₂O)]CH₂CH₃, CH₃CH₂O[(CH₂CH(CH₃)O)(CH(CH₃)CH₂O)(CH₂CH₂CH₂O)]CH₂CH₃, CH₃OCH₂CH(CH₃)OCH₂CH₂CH₂CH₃, CH₃O(CH₂CH(CH₃)O)₂CH₂CH₂CH₂CH₃, CH₃O(CH₂CH(CH₃)O)₃CH₂CH₂CH₂CH₃, CH₃O(CH₂CH(CH₃)O)₄CH₂CH₂CH₂CH₃, CH₃O(CH₂CH(CH₃)O)₅CH₂CH₂CH₂CH₃, CH₃OCH(CH₃)CH₂OCH₂CH₂CH₂CH₃, CH₃O(CH(CH₃)CH₂O)₂CH₂CH₂CH₂CH₃, CH₃O(CH(CH₃)CH₂O)₃CH₂CH₂CH₂CH₃, CH₃O(CH(CH₃)CH₂O)₄CH₂CH₂CH₂CH₃, CH₃O(CH(CH₃)CH₂O)₅CH₂CH₂CH₂CH₃, CH₃OCH₂CH₂CH₂OCH₂CH₂CH₂CH₃, CH₃O(CH₂CH₂CH₂O)₂CH₂CH₂CH₂CH₃, CH₃O(CH₂CH₂CH₂O)₃CH₂CH₂CH₂CH₃, CH₃O(CH₂CH₂CH₂O)₄CH₂CH₂CH₂CH₃, CH₃O(CH₂CH₂CH₂O)₅CH₂CH₂CH₂CH₃, CH₃O[(CH₂CH(CH₃)O)(CH(CH₃)CH₂O)]CH₂CH₂CH₂CH₃, CH₃O[(CH₂CH(CH₃)O)(CH₂CH₂CH₂O)]CH₂CH₂CH₂CH₃, CH₃O[(CH₂CH(CH₃)O)(CH(CH₃)CH₂O)(CH₂CH₂CH₂O)]CH₂CH₂CH₂CH₃, and the like, and one or more types of compounds selected from the above examples may be combined and used.

Compounds such as those described above include compounds having a propylene glycol backbone and alkoxy groups at both terminal ends thereof, but the propylene glycol backbone preferably has a structure in which a plurality of 1,2-propylene glycols is condensed (i.e., a compound in which 1 in Formula (4) is 2 or greater). Such effects as those described above can thereby be more significantly demonstrated, the color filter ink can be endowed with particularly excellent discharge stability and long-term storage properties (storage stability), and the manufactured color filter can be endowed with particularly excellent durability. Unevenness of color, saturation, and the like in different regions of the color filter can also be more effectively suppressed, and particularly excellent uniformity of characteristics between individual units can be obtained. Examples of compounds (liquid media) having a structure in which a plurality of 1,2-propylene glycols is condensed in this manner include CH₃O(CH₂CH(CH₃)O)₂CH₃, CH₃O(CH₂CH(CH₃)O)₃CH₃, CH₃O(CH₂CH(CH₃)O)₄CH₃, CH₃O(CH₂CH(CH₃)O)₅CH₃, CH₃O[(CH₂CH(CH₃)O)(CH(CH₃)CH₂O)]CH₃, CH₃O[(CH₂CH(CH₃)O)(CH(CH₃)CH₂O)(CH₂CH₂CH₂O)]CH₃, CH₃CH₂O(CH₂CH(CH₃)O)₂CH₃, CH₃CH₂O(CH₂CH(CH₃)O)₃CH₃, CH₃CH₂O(CH₂CH(CH₃)O)₄CH₃, CH₃CH₂O(CH₂CH(CH₃)O)₅CH₃, CH₃CH₂O(CH(CH₃)CH₂O)₂CH₃, CH₃CH₂O(CH(CH₃)CH₂O)₃CH₃, CH₃CH₂O(CH(CH₃)CH₂O)₄CH₃, CH₃CH₂O(CH(CH₃)CH₂O)₅CH₃, CH₃CH₂O[(CH₂CH(CH₃)O)(CH(CH₃)CH₂O)]CH₃, CH₃CH₂O[(CH₂CH(CH₃)O)(CH(CH₃)CH₂O)(CH₂CH₂CH₂O)]CH₃, CH₃CH₂O(CH₂CH(CH₃)O)₂CH₂CH₃, CH₃CH₂O(CH₂CH(CH₃)O)₃CH₂CH₃, CH₃CH₂O(CH₂CH(CH₃)O)₄CH₂CH₃, CH₃CH₂O(CH₂CH(CH₃O)₅CH₂CH₃, CH₃CH₂O[(CH₂CH(CH₃)O)(CH(CH₃)CH₂O)]CH₂CH₃, CH₃CH₂O[(CH₂CH(CH₃)O)(CH(CH₃)CH₂O)(CH₂CH₂CH₂O)]CH₂CH₃, CH₃O(CH₂CH(CH₃)O)₂CH₂CH₂CH₂CH₃, CH₃O(CH₂CH(CH₃)O)₃CH₂CH₂CH₂CH₃, CH₃O(CH₂CH(CH₃)O)₄CH₂CH₂CH₂CH₃, CH₃O(CH₂CH(CH₃)O)₅CH₂CH₂CH₂CH₃, CH₃O(CH(CH₃)CH₂O)₂CH₂CH₂CH₂CH₃, CH₃O(CH(CH₃)CH₂O)₃CH₂CH₂CH₂CH₃, CH₃O(CH(CH₃)CH₂O)₄CH₂CH₂CH₂CH₃, CH₃O(CH(CH₃)CH₂O)₅CH₂CH₂CH₂CH₃, CH₃O[(CH₂CH(CH₃)O)(CH(CH₃)CH₂O)]CH₂CH₂CH₂CH₃, CH₃O[(CH₂CH(CH₃)O)(CH(CH₃)CH₂O)(CH₂CH₂CH₂O)]CH₂CH₂CH₂CH₃, and the like.

The propylene glycol backbone constituting the aforementioned compound preferably has a structure in which two to three propylene glycols are condensed (i.e., “l+m+n” in Formula (4) is 2 to 3). Such effects as those described above can thereby be more significantly demonstrated, the color filter ink can be endowed with particularly excellent discharge stability and long-term storage properties (storage stability), and the manufactured color filter can be endowed with particularly excellent durability. Unevenness of color, saturation, and the like in different regions of the color filter can also be more effectively suppressed, and particularly excellent uniformity of characteristics between individual units can be obtained. Examples of compounds (liquid media) having a structure in which two to three propylene glycols are condensed in this manner include CH₃O(CH₂CH(CH₃)O)₂CH₃, CH₃O(CH₂CH(CH₃)O)₃CH₃, CH₃O(CH₂CH₂CH₂O)₂CH₃, CH₃O(CH₂CH₂CH₂O)₃CH₃, CH₃O[(CH₂CH(CH₃)O)(CH(CH₃)CH₂O)]CH₃, CH₃O[(CH₂CH(CH₃)O)(CH₂CH₂CH₂O)]CH₃, CH₃O[(CH₂CH(CH₃)O)(CH(CH₃)CH₂O)(CH₂CH₂CH₂O)]CH₃, CH₃CH₂O(CH₂CH(CH₃)O)₂CH₃, CH₃CH₂O(CH₂CH(CH₃)O)₃CH₃, CH₃CH₂O(CH(CH₃)CH₂O)₂CH₃, CH₃CH₂O(CH(CH₃)CH₂O)₃CH₃, CH₃CH₂O(CH₂CH₂CH₂O)₂CH₃, CH₃CH₂O(CH₂CH₂CH₂O)₃CH₃, CH₃CH₂O[(CH₃CH(CH₃)O)(CH(CH₃)CH₂O)]CH₃, CH₃CH₂O[(CH₂CH(CH₃)O)(CH₂CH₂CH₂O)]CH₃, CH₃CH₂O[(CH₂CH(CH₃)O)(CH(CH₃)CH₂O)(CH₂CH₂CH₂O)]CH₃, CH₃CH₂O(CH₂CH(CH₃)O)₂CH₂CH₃, CH₃CH₂O(CH₂CH(CH₃)O)₃CH₂CH₃, CH₃CH₂O(CH₂CH₂CH₂O)₂CH₂CH₃, CH₃CH₂O(CH₂CH₂CH₂O)₃CH₂CH₃, CH₃CH₂O[(CH₂CH(CH₃)O)(CH(CH₃)CH₂O)]CH₂CH₃, CH₃CH₂O[(CH₂CH(CH₃)O)(CH₂CH₂CH₂O)]CH₂CH₃, CH₃CH₂O[(CH₂CH(CH₃)O)(CH(CH₃)CH₂O)(CH₂CH₂CH₂O)]CH₂CH₃, CH₃O(CH₂CH(CH₃)O)₂CH₂CH₂CH₂CH₃, CH₃O(CH₂CH(CH₃)O)₃CH₂CH₂CH₂CH₃, CH₃O(CH(CH₃)CH₂O)₂CH₂CH₂CH₂CH₃, CH₃O(CH(CH₃)CH₂O)₃CH₂CH₂CH₂CH₃, CH₃O(CH₂CH₂CH₂O)₂CH₂CH₂CH₂CH₃, CH₃O(CH₂CH₂CH₂O)₃CH₂CH₂CH₂CH₃, CH₃O[(CH₂CH(CH₃)O)(CH(CH₃)CH₂O)]CH₂CH₂CH₂CH₃, CH₃O[(CH₂CH(CH₃)O)(CH₂CH₂CH₂O)]CH₂CH₂CH₂CH₃, CH₃O[(CH₂CH(CH₃)O)(CH(CH₃)CH₂O)(CH₂CH₂CH₂O)]CH₂CH₂CH₂CH₃, and the like.

The boiling point of the liquid medium at atmospheric pressure (1 atm) is preferably 160 to 300° C., more preferably 180 to 290° C., and even more preferably 200 to 280° C. When the boiling point of the liquid medium at atmospheric pressure is within this range, blockage and the like in the droplet discharge head for discharging the color filter ink can be more effectively prevented, and the color filter can be manufactured with particularly excellent productivity.

The vapor pressure of the liquid medium at 25° C. is preferably 0.7 mmHg or lower, and more preferably 0.1 mmHg or lower. When the vapor pressure of the liquid medium is within this range, blockage and the like in the droplet discharge head for discharging the color filter ink can be more effectively prevented, and the color filter can be manufactured with particularly excellent productivity.

The content ratio of the liquid medium in the color filter ink is preferably 50 to 98 wt %, more preferably 70 to 95 wt %, and even more preferably 80 to 93 wt %. When the content ratio of the liquid medium is within this range, the manufactured color filter can be endowed with excellent durability while the discharge properties of the color filter ink from the droplet discharge head are made particularly excellent. Adequate color saturation can also be maintained in the manufactured color filter.

### Dispersing Agent

A dispersing agent may be included in the color filter ink. Excellent dispersion stability of the pigment can thereby be obtained, and the color filter ink can be endowed with excellent storage stability even when the color filter ink includes a minimally dispersible pigment, for example.

Examples of dispersing agents include cationic, anionic, nonionic, amphoteric, silicone-based, fluorine-based, and other surfactants. Specific examples of surfactants include polyoxyethylene lauryl ether, polyoxyethylene stearyl ether, polyoxyethylene oleyl ether, and other polyoxyethylene alkyl ethers; polyoxyethylene n-octylphenyl ether, polyoxyethylene n-nonylphenyl ether, and other polyoxyethylene alkylphenyl ethers; polyethylene glycol dilaurate, polyethylene glycol distearate, and other polyethylene glycol diesters; sorbitan fatty acid esters; fatty acid-modified polyesters; tertiary amine-modified polyurethanes; polyethylene imines and the like; as well as the compounds known by the product names below: KP (manufactured by Shin-Etsu Chemical), Polyflow (manufactured by Kyoeisha Chemical), F-TOP (manufactured by Tochem Products), Megafac (manufactured by Dainippon Ink & Chemicals), Flowrad (manufactured by Sumitomo 3M), Asahi Guard and Surflon (both manufactured by Asahi Glass), Disperbyk (manufactured by Byk Chemie Japan), Solsperse 3000, 5000, 11200, 12000, 13240, 13650, 13940, 16000, 17000, 18000, 20000, 21000, 22000, 24000SC, and 24000GR (manufactured by Nippon Lubrizol), and other compounds.

A compound provided with a cyamelide backbone, for example, may be used as the dispersing agent. The use of such a compound as the dispersing agent makes it possible to obtain particularly excellent dispersion properties of the pigment in the dispersion medium in which the resin material such as described above is dissolved, and to endow the color filter ink with particularly excellent discharge stability. Such excellent effects are obtained by the synergistic effects of using a resin material such as described above (resin material including the polymer A and the polymer B) jointly with a compound provided with a cyamelide backbone, and not merely by using a compound provided with a cyamelide backbone as the dispersing agent.

A compound having the partial structure indicated by Formula (5) and Formula (6) below, for example, may be used as the dispersing agent. Using such a compound as the dispersing agent makes it possible to obtain particularly excellent dispersion properties of the colorant (pigment) in the color filter ink, and to endow the color filter ink with particularly excellent discharge stability.

Formula (5)

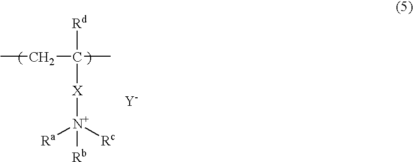

In Formula (5), R^{a}, R^{b}, and R^{c} are each independently a hydrogen atom, or a cyclic or chain hydrocarbon group which may be substituted; or two or more of R^{a}, R^{b}, and R^{c} bond with each other and form a cyclic structure; R^{d} is a hydrogen atom or a methyl group; X is a bivalent linking group; and Y⁻ is a counter anion.

Formula (6)

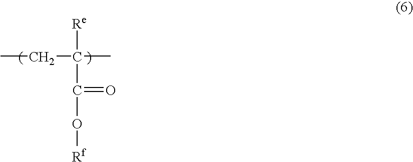

In Formula (6), R^{e} is a hydrogen atom or a methyl group; R^{f} is a cyclic or chain alkyl group which may have a substituted group, an aryl group which may have a substituted group, or an aralkyl group which may have a substituted group.

The content ratio of the dispersing agent in the color filter ink is preferably 0.5 to 15 wt %, and more preferably 0.5 to 8 wt %.

### Other Components

The color filter ink may be one that contains various other components as required. Examples of such components (other additives) include various cross-linking agents; thermoacid generators such as diazonium salt, iodonium salt, sulfonium salt, phosphonium salt, selenium salt, oxonium salt, ammonium salt, benzothiazolium salt, and other onium salts; diazonium salt, iodonium salt, sulfonium salt, phosphonium salt, selenium salt, oxonium salt, ammonium salt, and other photoacid generators; polymerization initiators; acid crosslinking agents; intensifiers; photostabilizers; adhesive improvers; copper phthalocyanine derivatives and other blue pigment derivatives, and yellow pigment derivatives and other dispersing aids; glass, alumina, and other fillers; polyvinyl alcohol, polyethylene glycol monoalkyl ether, polyfluoro alkyl acrylate, and other polymer compounds; vinyl trimethoxysilane, vinyl triethoxysilane, vinyl tris(2-methoxy ethoxy)silane, N-(2-amino ethyl)-3-amino propyl methyl dimethoxysilane, N-(2-amino ethyl)-3-amino propyl trimethoxysilane, 3-amino propyl triethoxysilane, 3-glycidoxy propyl trimethoxysilane, 3-glycidoxy propyl methyl dimethoxysilane, 2-(3,4-epoxy cyclohexyl)ethyl trimethoxysilane, 3-chloro propyl methyl dimethoxysilane, 3-chloro propyl trimethoxysilane, 3-methacryloxy propyl trimethoxysilane, 3-mercapto propyl trimethoxysilane, and other adhesion accelerants; 2,2-thiobis(4-methyl-6-t-butyl phenol), 2,6-di-t-butyl phenol, and other antioxidants; 2-(3-t-butyl-5-methyl-2-hydroxy phenyl)-5-chlorobenzotriazole, alcoxy benzophenone, and other UV absorbers; sodium polyacrylate, and other anti-coagulants; methanol, ethanol, i-propanol, n-butanol, glycerin, and other inkjet discharge performance stabilizers; and surfactants by the following product names, Eftop EF301, Eftop EF303, and Eftop EF352 (manufactured by Shin Akita Kasei Co., Ltd.), Megafac F171, Megafac F172, Megafac F173, and Megafac F178K (manufactured by Dainippon Ink and Chemicals, Inc.), Fluorad FC-430 and Fluorad FC431 (manufactured by Sumitomo 3M), Asahi Guard AG710, Surflon S-382, Surflon SC101, Surflon SC102, Surflon SC103, Surflon SC104, Surflon SC105, Surflon SC106 (manufactured by Asahi Glass Company), KP341 (manufactured by Shin-etsu Chemical Co., Ltd.), Polyflow No. 75, Polyflow No. 95 (manufactured by Kyoeisha Yushi Chemical Co., Ltd.), as well as other products.

Examples of cross-linking agents that may be used include polycarboxylic acid anhydrides, polycarboxylic acids, polyfunctional epoxy monomers, polyfunctional acrylic monomers, polyfunctional vinyl ether monomers, and polyfunctional oxetane monomers. Specific examples of polycarboxylic acid anhydrides include phthalic anhydride, itaconic anhydride, succinic anhydride, citraconic anhydride, dodecenyl succinic anhydride, tricarballylic anhydride, maleic anhydride, hexahydrophthalic anhydride, dimethyl tetrahydrophthalic anhydride, himic anhydride, nadic anhydride, and other aliphatic or alicyclic dicarboxylic anhydrides; 1,2,3,4-butane tetracarboxylic acid dianhydride, cyclopentane tetracarboxylic acid, maleic acid, itaconic acid, and other aliphatic polycarboxylic acids; hexahydrophthalic acid, 1,2-cyclohexane dicarboxylic acid, 1,2,4-cyclohexane tricarboxylic acid, cyclopentane tetracarboxylic acid, and other aliphatic polycarboxylic acids; and phthalic acid, isophthalic acid, terephthalic acid, pyromellitic acid, trimellitic acid, 1,4,5,8-naphthalene tetracarboxylic acid, benzophenone tetracarboxylic acid, and other aromatic polycarboxylic acid, but among these, aromatic polycarboxylic acid is preferred. Specific examples of a polyfunctional epoxy monomer include the product name Celloxide 2021 manufactured by Daicel Chemical Industries, the product name Epolead GT401 manufactured by Daicel Chemical Industries, the product name Epolead PB3600 manufactured by Daicel Chemical Industries, bisphenol A, hydrogenated bisphenol A, and triglycidyl isocyanurate. Specific example of a polyfunctional acrylic monomer include pentaerythritol ethoxytetraacrylate, pentaerythritol tetraacrylate, pentaerythritol triacrylate, pentaerythritol ethoxytetraacrylate, ditrimethylol propane tetraacrylate, trimethylolpropane triacrylate, trimethylol propane ethoxytriacrylate, dipentaerythritol hexaacrylate trimethallyl isocyanurate, and triaryl isocyanurate. Examples of a polyfunctional vinyl ether monomer include 1,4-butanediol vinyl ether, 1,6-hexanediol divinyl ether, nonanediol divinyl ether, cyclohexanediol divinyl ether, cyclohexanedimethanol divinyl ether, triethylene glycol divinyl ether, trimethylolpropane trivinyl ether, and pentaerythritol tetravinyl ether. Examples of polyfunctional oxetane monomers include xylylene dioxetane, biphenyl-type oxetane, and novolac-type oxetane.

The thermoacid generator is a component for generating acid by applying heat, and particularly preferred among those described above are sulfonium salt and benzothiazolium salt. More specific examples of thermoacid generators in terms of product names include Sunaid SI-45, Sunaid SI-47, Sunaid SI-60, Sunaid SI-60L, Sunaid SI-80, Sunaid SI-80L, Sunaid SI-100, Sunaid SI-100L, Sunaid SI-145, Sunaid SI-150, Sunaid SI-160, Sunaid SI-110L, Sunaid SI-180L (all product names, manufactured by Sanshin Chemical Industry Co., Ltd.), CI-2921, CI-2920, CI-2946, CI-3128, CI-2624, CI-2639, CI-2064 (all product names, manufactured by Nippon Soda Co., Ltd.), CP-66, CP-77 (product names, manufactured by Adeka Corporation), and FC-520 (product name, manufactured by 3M Company).

The photoacid generator is a component for generating acid by using light, and more specific examples include the product names Cyracure UVI-6970, Cyracure UVI-6974, Cyracure UVI-6990, Cyracure UVI-950 (all product names, manufactured by US Union Carbide), Irgacure 261 (product name, Ciba Specialty Chemicals), SP-150, SP-151, SP-170, Optomer SP-171 (all product names, manufactured by Adeka Corporation), CG-24-61 (product name, manufactured by Ciba Specialty Chemicals), Daicat II (product name, manufactured by Daicel Chemical Industries, Ltd.), UVAC 1591 (product name, manufactured by Daicel UCB Co., Ltd.), CI-2064, CI-2639, CI-2624, CI-2481, CI-2734, CI-2855, CI-2823, CI-2758 (product name, manufactured by Nippon Soda Co., Ltd.), PI-2074 (product name, manufactured by Rhone Poulenc, pentafluorophenyl borate tolyl cumyl iodonium), FFC509 (product name, manufactured by 3M Company), BBI-102, BBI-101, BBI-103, MPI-103, TPS-103, MDS-103, DTS-103, NAT-103, NDS-103 (product name, manufactured by Midori Kagaku Co., Ltd.), and CD-1012 (product name, manufactured by Sartomer Co., Inc.).

The viscosity (viscosity measured using a vibrating viscosimeter) of the color filter ink at 25° C. is not particularly limited, but is preferably 4 to 10 mP·s, and more preferably 5 to 9.5 mP·s. When the viscosity of the color filter ink is a value within the stated range, the occurrence of clogging and the like in the droplet discharge head can be more reliably prevented while keeping variation in droplet amount of the color filter ink to be discharged particularly small in droplet discharges using an inkjet method such as the one described later. The viscosity of the color filter ink can be measured using a vibrating viscosimeter, for example, and can particularly be performed in accordance with JIS Z8809.

### Ink Set

The color filter ink such as that described above is used in the manufacture of a color filter using an inkjet method. A color filter ordinarily has coloring units having a plurality of colors (ordinarily, RGB corresponding to the three primary colors of light) in correlation with a full color display. A plurality of types of color filter ink that correspond to the plurality of colors of colored portions is used in the formation of the colored portions. In other words, an ink set provided with a plurality of colors of color filter ink is used in the manufacture of a color filter. In the present embodiment, the color filter ink such as that described above may be used in the formation of at least one colored portion in the manufacture of a color filter, but the color filter ink is preferably used in the formation of all colors of colored portions.

### Color Filter

Following is a description of an example of a color filter manufactured using the color filter ink (ink set) described above.

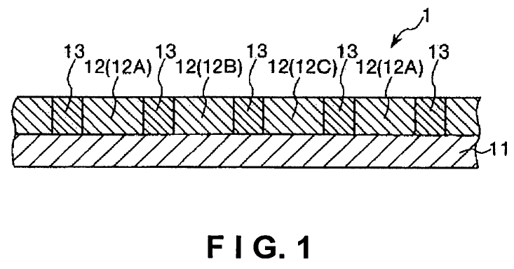

FIG. 1 is a cross-sectional view showing a preferred embodiment of the color filter of the present invention.

A color filter 1 is provided with a substrate 11 and colored portions 12 formed using the color filter ink described above, as shown in FIG. 1. The colored portions 12 are provided with a first colored portion 12A, a second colored portion 12B, and a third colored portion 12C, having mutually different colors. A partition wall 13 is disposed between adjacent colored portions 12.

### Substrate

The substrate 11 is a plate-shaped member having optical transparency, and has a function for holding the colored portions 12 and the partition wall 13.

It is preferred that the substrate 11 be essentially composed of a transparent material. A clearer image can thereby be formed by light transmitted through the color filter 1.

The substrate 11 is preferably one having excellent heat resistance and mechanical strength. Deformations or the like caused by, e.g., heat applied during the manufacture of the color filter 1 can thereby be reliably prevented. Examples of a constituent material of the substrate 11 that satisfies such conditions include glass, silicon, polycarbonate, polyester, aromatic polyamide, polyamidoimide, polyimide, norbornene-based ring-opening polymers, and hydrogenated substances.

### Colored Portions

The colored portions 12 are formed using a color filter ink such as that described above.

The colored portions 12 are formed using a color filter ink such as that described above, and therefore have little variation in characteristics between pixels, and unintentional color mixing (mixing of a plurality of color filter inks) and the like is reliably prevented. For this reason, the color filter 1 is highly reliable in that the occurrence of unevenness of color and saturation, and the like is reduced.

Each colored portion 12 is disposed inside a cell 14, which is an area enclosed by a later-described partition wall 13.

The first colored portion 12A, the second colored portion 12B, and the third colored portion 12C have mutually different colors. For example, the first colored portion 12A can be a red filter area (R), second colored portion 12B can be a green filter area (G), and the third colored portion 12C can be a blue filter area (B). The colored portions 12A, 12B, 12C as a single set of different colors constitute a single pixel. A prescribed number of the colored portions 12 are disposed in the lateral and longitudinal directions in the color filter 1. For example, when the color filter 1 is a color filter for high definition, 1366×768 pixels are disposed; when the color filter is a color filter for full high definition, 1920×1080 pixels are disposed; and when the color filter is a color filter for super high definition, 7680×4320 pixels are disposed. The color filter 1 may be provided with, e.g., spare pixels outside of the effective area.

### Partition Wall

A partition wall (bank) 13 is disposed between adjacent colored portions 12. Adjacent colored portions 12 can thereby be reliably prevented from color mixing, and as a result, a sharp image can be reliably displayed.

The partition wall 13 may be composed of a transparent material, but is preferably composed of material having light-blocking properties. An image with excellent contrast can thereby be displayed. The color of the partition wall (light-blocking portion) 13 is not particularly limited, but black is preferred. Accordingly, the contrast of a displayed image is particularly good.

The height of the partition wall 13 is not particularly limited, but is preferably greater than the thickness of the colored portions 12. Color mixing between adjacent colored portions 12 can thereby be reliably prevented. The specific thickness of the partition wall 13 is preferably 0.1 to 10 μm, and more preferably 0.5 to 3.5 μm. Color mixing between adjacent colored portions 12 can thereby be reliably prevented, and image display devices and electronic devices provided with the color filter 1 can be endowed with excellent visual angle characteristics.

The partition wall 13 may be composed of any material, but is preferably composed principally of a resin material, for example. Accordingly, a partition wall 13 having a desired shape can be easily formed using a method described hereinafter. In the case that the partition wall 13 functions as a light-blocking portion, carbon black or another light-absorbing material may be included as a constituent element of the partition wall.

### Method for Manufacturing Color Filter

Next, an example of the method for manufacturing the color filter 1 will be described.

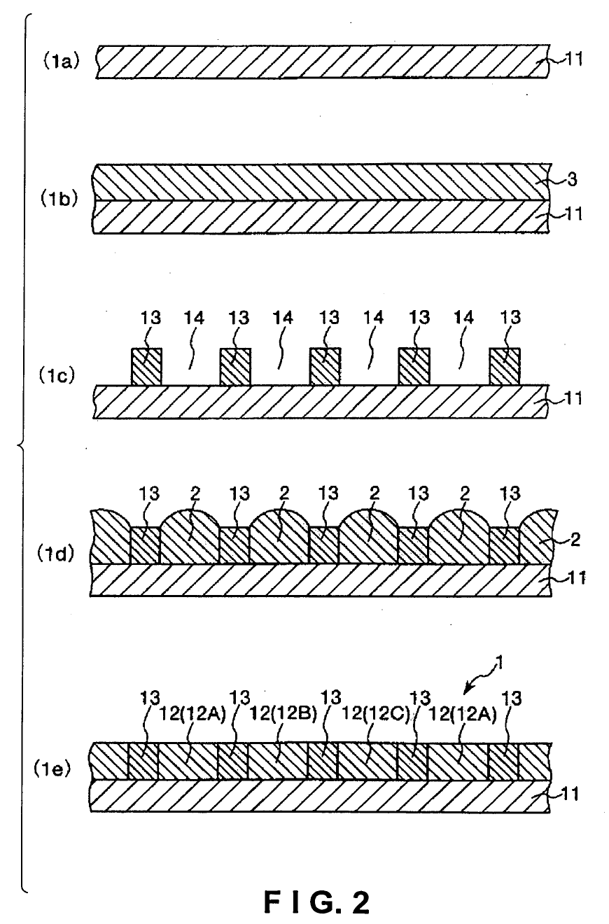

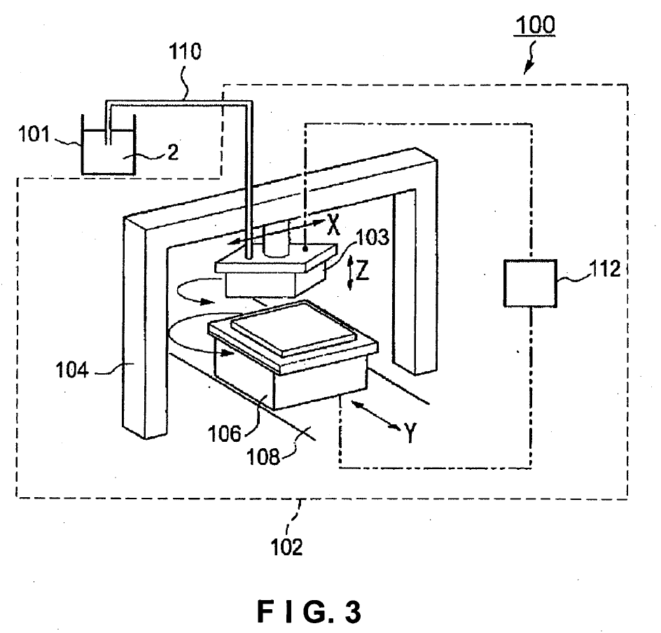

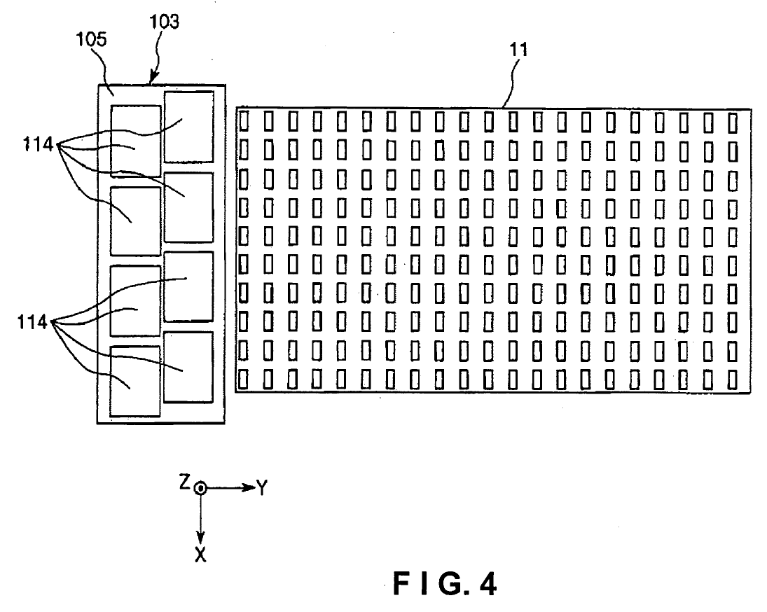

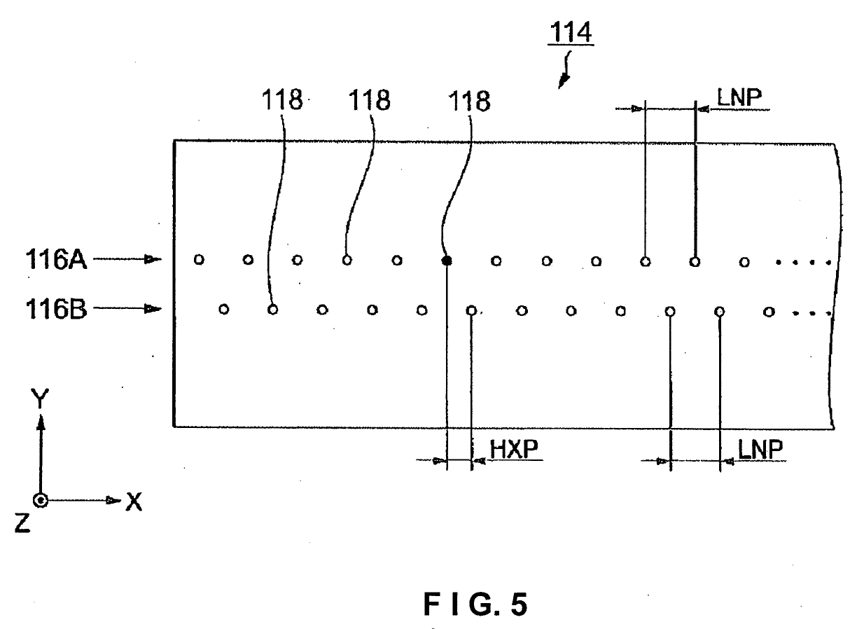

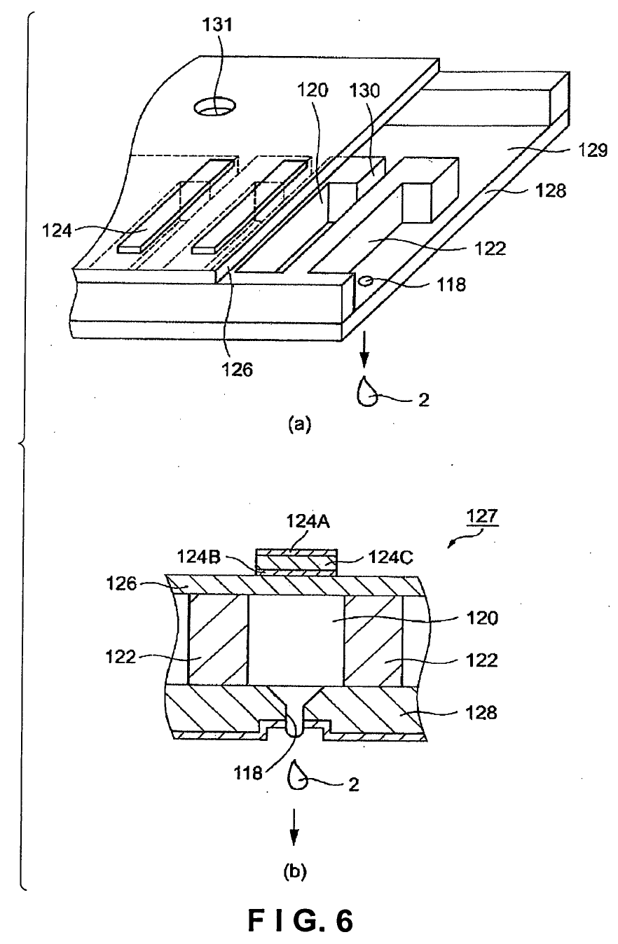

FIG. 2 is a cross-sectional view showing a method for manufacturing a color filter; FIG. 3 is a perspective view showing the droplet discharge device used in the manufacture of the color filter; FIG. 4 is a view of droplet discharge unit in the droplet discharge device shown in FIG. 3, as seen from the stage side; FIG. 5 is a view showing the bottom surface of the droplet discharge head in the droplet discharge device shown in FIG. 3; and FIG. 6 is a view showing the droplet discharge head in the droplet discharge device shown in FIG. 3, wherein FIG. 6(a) is a cross-sectional perspective view and FIG. 6(b) is a cross-sectional view.

The present embodiment has a substrate preparation step (1a) for preparing a substrate 11, a partition wall formation step (1b, 1c) for forming a partition wall 13 on the substrate 11, an ink application step (1d) for applying color filter ink 2 into an area surrounded by the partition wall 13 by using an inkjet method, and a colored portion formation step (1e) for forming solid colored portions 12 by removing liquid medium from the color filter ink 2 and curing the resin material, as shown in FIG. 2.

### Substrate Preparation Step

First, a substrate 1 is prepared (1a). It is preferred that the substrate 11 to be prepared in the present step undergo a washing treatment. The substrate 11 to be prepared in the present step may be washed by chemical treatment using a silane-coupling agent or the like, a plasma treatment, ion plating, sputtering, gas phase reaction, vacuum deposition, or another suitable washing treatment.

### Partition Wall Formation Step

Next, a radiation-sensitive composition is applied to substantially the entire surface of one of the surfaces of the substrate 11 to form (1b) a coated film 3. A prebaking treatment may be performed as required after the radiation-sensitive composition has been applied to the substrate 11. The prebaking treatment may be carried out under the conditions of, e.g., a heating temperature of 50 to 150° C. and a heating time of 30 to 600 seconds.

Next, a partition wall 13 is formed (1c) by irradiating the surface via a photomask, performing a post exposure bake (PEB), and carrying out a development treatment using an alkali development fluid. PEB can be carried out under the following example conditions: a heating temperature of 50 to 150° C., a heating time of 30 to 600 seconds, and a radiation intensity of 1 to 500 mJ/cm². The development treatment can be performed using, e.g., fluid overflow, dipping, vibration soaking, or another method, and the development treatment time can be set to 10 to 300 seconds, for example. After the development treatment, a post baking treatment may be performed as required. The post baking treatment can be carried out under the following example conditions: a heating temperature of 150 to 280° C. and a heating time of 3 to 120 minutes.

### Ink Application Step

Next, the color filter ink 2 is applied (1d) to the cells 14 surrounded by the partition wall 13 using the inkjet method.

The present step is carried out using a plurality of types of color filter inks 2 that correspond to the plurality of colors of the colored portions 12 to be formed. In this case, a partition wall 13 is provided, and mixing of two or more color filter inks 2 can therefore be reliably prevented.

The color filter ink 2 is discharged using a droplet discharge device such as that shown in FIGS. 3 to 6.

The droplet discharge device 100 used in the present step is provided with a tank 101 for holding the color filter ink 2, a tube 110, and a discharge scan unit 102 to which the color filter ink 2 is fed from the tank 101 via the tube 110, as shown in FIG. 3. The discharge scan unit 102 is provided with droplet discharge unit 103 in which a plurality of droplet discharge heads (inkjet heads) 114 is mounted on a carriage 105, a first position controller 104 (movement means) for controlling the position of the droplet discharge unit 103, a stage 106 for holding the substrate 11 (hereinafter simply referred to as “substrate 11”) on which the partition wall 13 is formed in an aforementioned step, a second position controller 108 (movement means) for controlling the position of the stage 106, and control means 112. The tank 101 and the plurality of droplet discharge heads 114 in the droplet discharge unit 103 are connected by the tube 110, and the color filter ink 2 is fed by compressed air from the tank 101 to each of the plurality of droplet discharge heads 114.

The first position controller 104 moves the droplet discharge unit 103 along the X-axis direction and Z-axis direction orthogonal to the X-axis direction, in accordance with a signal from the control means 112. The first position controller 104 also has a function for rotating the droplet discharge unit 103 about the axis parallel to the Z-axis. In the present embodiment, the Z-axis direction is the direction parallel to the perpendicular direction (i.e., the direction of gravitational acceleration). The second position controller 108 moves the stage 106 along the Y-axis direction, which is orthogonal to both the X-axis direction and the Z-axis direction. The second position controller 108 also has a function for rotating the stage 106 about the axis parallel to the Z-axis.

The stage 106 has a surface parallel to both the X-axis direction and the Y-axis direction. The stage 106 is configured so as to be capable of securing or holding the substrate 11 on the planar surface thereof, the substrate having the cells 14 in which the color filter ink 2 is to be applied.

As described above, the droplet discharge unit 103 is moved in the X-axis direction by the first position controller 104. On the other hand, the stage 106 is moved in the Y-axis direction by the second position controller 108. In other words, the relative position of the droplet discharge heads 114 in relation to the stage 106 is changed by the first position controller 104 and the second position controller 108 (the substrate 11 held on the stage 106 and the droplet discharge unit 103 move in a relative fashion).

The control means 112 is configured so as to receive from an external information processor discharge data that express the relative position in which the color filter ink 2 is to be discharged.

The droplet discharge unit 103 has a plurality of droplet discharge heads 114, which have substantially the same structure as each other, and a carriage 105 for holding the droplet discharge heads 114, as shown in FIG. 4. In the present embodiment, the number of droplet discharge heads 114 held in the droplet discharge unit 103 is eight. Each of the droplet discharge heads 114 has a bottom surface on which a plurality of later-described nozzles 118 is disposed. The shape of the bottom surface of each of the droplet discharge heads 114 is a polygon having two short sides and two long sides. The bottom surface of the droplet discharge heads 114 held in the droplet discharge unit 103 faces the stage 106 side, and the long-side direction and the short-side direction of the droplet discharge heads 114 are parallel to the X-axis direction and the Y-axis direction, respectively.

The droplet discharge heads 114 have a plurality of nozzles 118 aligned in the X-axis direction, as shown in FIG. 5. The plurality of nozzles 118 is disposed so that a nozzle pitch HXP in the X-axis direction in the droplet discharge heads 114 has a prescribed value. The specific value of the nozzle pitch HXP is not particularly limited, but may be 50 to 90 μm, for example. In this case, “the nozzle pitch HXP in the X-axis direction in the droplet discharge heads 114” corresponds to the pitch between a plurality of nozzle images obtained by projecting all of the nozzles 118 in the droplet discharge heads 114 on the X axis along the Y-axis direction.

In the present embodiment, the plurality of nozzles 118 in the droplet discharge heads 114 forms a nozzle row 116A and a nozzle row 116B, both of which extend in the X-axis direction. The nozzle row 116A and the nozzle row 116B are disposed in parallel across an interval. In the present embodiment, 90 nozzles 118 are aligned in a row in the X-axis direction with a fixed interval LNP in each nozzle row 116A and nozzle row 116B. The specific value of LNP is not particularly limited, but may be 100 to 180 μm, for example.

The position of the nozzle row 116B is offset in the positive direction of the X-axis direction by half the length of the nozzle pitch LNP in relation to the position of the nozzle row 116A. For this reason, the nozzle pitch HXP in the X-axis direction of the droplet discharge heads 114 is half the length of the nozzle pitch LNP of the nozzle row 116A (or the nozzle row 116B).

Therefore, the nozzle line density in the X-axis direction of the droplet discharge heads 114 is twice the nozzle line density of the nozzle row 116A (or the nozzle row 116B). In the present specification, “the nozzle line density in the X-axis direction” corresponds to the number per unit length of the plurality of nozzle images obtained by projecting a plurality of nozzles on the X-axis along the Y-axis direction. Naturally, the number of nozzle rows included in the droplet discharge heads 114 is not limited to two rows. The droplet discharge heads 114 may include M number of nozzle rows. In this case, M is a natural number of 1 or higher. In this case, the plurality of nozzles 118 in each of the M number of nozzle rows is aligned at a pitch having a length that is M times that of the nozzle pitch HXP. In the case that M is a natural number of 2 or higher, another (M−1) number of nozzle rows are offset in the X-axis direction without overlapping, by a length i times that of the nozzle pitch HXP, in relation to a single nozzle row among the M number of nozzle rows. Here, i is a natural number from 1 to (M−1).

In the present embodiment, since the nozzle row 116A and the nozzle row 116B are each composed of 90 nozzles 118, a single droplet discharge head 114 has 180 nozzles 118. However, five nozzles at each end of the nozzle row 116A are set as “reserve nozzles.” Similarly, five nozzles at each end of the nozzle row 116B are set as “reserve nozzles.” The color filter ink 2 is not discharged from these 20 “reserve nozzles.” For this reason, 160 nozzles 118 among the 180 nozzles 118 in the droplet discharge heads 114 function as nozzles for discharging the color filter ink 2.

In the droplet discharge unit 103, the plurality of droplet discharge heads 114 is disposed in two rows along the X-axis direction, as shown in FIG. 4. One of the rows of droplet discharge heads 114 and the other row of droplet discharge heads 114 are disposed so that a portion of the droplet discharge heads overlap as viewed from the Y-axis direction, with consideration given to the reserve nozzles. The nozzles 118 for discharging the color filter ink 2 are thereby configured so as to be continuous in the X-axis direction at the nozzle pitch HXP across the length of the dimension in the X-axis direction of the substrate 11 in the droplet discharge unit 103.

In the droplet discharge unit 103 of the present embodiment, the droplet discharge heads 114 are disposed so as to cover the entire length of the dimension in the X-axis direction of the substrate 11. However, the droplet discharge unit in the present invention may cover a portion of the length of the dimension in the X-axis direction of the substrate 11.

Each of the droplet discharge heads 114 is an inkjet head, as shown in the diagram. More specifically, each of the droplet discharge heads 114 is provided with a vibration plate 126 and a nozzle plate 128. A fluid reservoir 129 in which the color filter ink 2 fed from the tank 101 via a hole 131 is constantly filled is positioned between the vibration plate 126 and the nozzle plate 128.

A plurality of partition walls 122 is disposed between the vibration plate 126 and the nozzle plate 128. The portions enclosed by the vibration plate 126, the nozzle plate 128, and a pair of partition walls 122 are cavities 120. Since the cavities 120 are disposed in correspondence with the nozzles 118, the number of cavities 120 and the number of nozzles 118 is the same. The color filter ink 2 is fed to the cavities 120 from the fluid reservoir 129 via supply ports 130 positioned between pairs of partition walls 122.

An oscillator 124 is positioned on the vibration plate 126 in correspondence with each of the cavities 120. The oscillator 124 includes a piezoelement 124C, and a pair of electrodes 124A, 124B that sandwich the piezoelement 124C. The color filter ink 2 is discharged from the corresponding nozzle 118 by applying a drive voltage between the pair of electrodes 124A, 124B. The shape of the nozzles 118 is adjusted so that the color filter ink 2 is discharged in the Z-axis direction from the nozzles 118.

The control means 112 (see FIG. 3) may be configured so as to independently apply signals to each of the plurality of oscillators 124. In other words, the volume of the color filter ink 2 discharged from the nozzles 118 can be controlled for each nozzle 118 in accordance with a signal from the control means 112. The control means 112 can also set the nozzles 118 that will perform a discharge operation during a coating scan, as well as the nozzles 118 that will not perform a discharge operation.

In the present specification, the portion that includes a single nozzle 118, a cavity 120 that corresponds to the nozzle 118, and the oscillator 124 that corresponds to the cavity 120 will be referred to as a “discharge portion 127”. In accordance with this is designation, a single droplet discharge head 114 has the same number of discharge portions 127 as the number of nozzles 118.

The color filter ink 2 corresponding to the plurality of colored portions 12 of the color filter 1 is applied to the cells 14 using such a droplet discharge device 100. The color filter ink 2 can be selectively applied with good efficiency in the cells 14 by using such a device. As described above, the color filter ink 2 has excellent stable discharge properties, and flight deflection, loss of stability in the droplet discharge quantity, and other problems are much less likely to occur, even when droplet discharge is carried out over a long period of time. Therefore, it is possible to reliably prevent problems such as the mixing (color mixing) of a plurality of types of ink used in the formation of colored portions having different colors, and variability in the color saturation between the plurality of colored portions in which the same color saturation is normally required. In the configuration of the diagrams, the droplet discharge device 100 has a tank 101 for holding the color filter ink 2, a tube 110, and other components for only one color, but these members may have a plurality of colors the correspond to the plurality of colored portions 12 of the color filter 1. Also, in the manufacture of the color filter 1, a plurality of droplet discharge devices 100 corresponding to a plurality of colored portions 12 may be used.

In the present invention, the droplet discharge heads 114 may use an electrostatic actuator in place of the piezoelement as the drive element. The droplet discharge heads 114 may have a configuration in which an electrothermal converter is used and color filter ink is discharged using the thermoexpansion of material produced by an electrothermal converter.

### Colored Portion Formation Step (Curing Step)

Next, the liquid medium is removed from the color filter ink 2 in the cells 14, and solid colored portions 12 are formed by curing the resin material (1e). The color filter 1 is obtained in this manner.

The present step, heating is ordinarily carried out, but in the present step, for example, treatments involving irradiation of active energy rays, treatments in which the substrate 11 to which the color filter ink 2 has been applied is placed under a reduced-pressure environment, and other treatments may also be performed. The curing reaction of the resin material can be made to proceed with good efficiency by irradiating active energy rays; the curing reaction of the resin material can be reliably promoted even when the heating temperature is relatively low; the occurrence of adverse effects on the substrate 11 and other components can reliably prevented; and other effects can be obtained. Examples of the active energy rays that may be used include light rays of various wavelengths, e.g., UV rays, X-rays, g-rays, i-rays, and excimer lasers. The substrate 11 on which the color filter ink 2 has been applied can be placed under a reduced-pressure environment, whereby the liquid medium can be removed with good efficiency, the shape of the colored portions in the pixels (cells) can be reliably made into good preferred shapes, the liquid medium can be reliably removed even when the heating temperature is relatively low, the occurrence of adverse effects on the substrate 11 and the like can be reliably prevented, and other effects can be obtained.

The heating temperature in the present step is not particularly limited, but 50 to 260° C. is preferred, and 80 to 240° C. is even more preferred.

### Image Display Device

Preferred embodiments of the liquid crystal display device, which is an image display device (electrooptic device) having the color filter 1, will next be described.

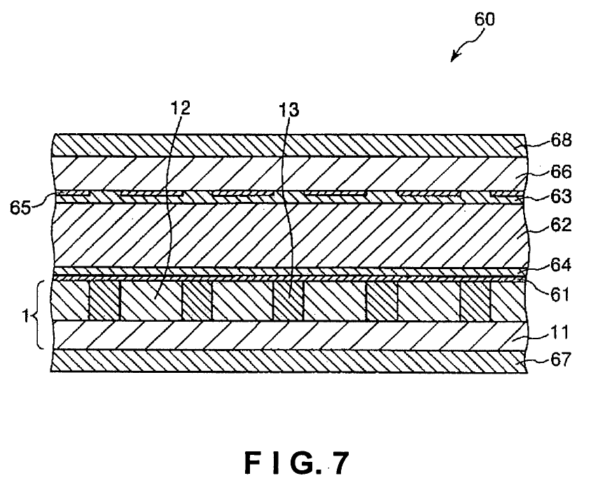

FIG. 7 is a cross-sectional view showing a preferred embodiment of the liquid crystal display device. As shown in the diagram, the liquid crystal display device 60 has a color filter 1, a substrate (opposing substrate) 66 arranged on the surface on which the colored portions 12 of the color filter 1 are disposed, a liquid crystal layer 62 composed of a liquid crystal sealed in the gaps between the color filter 1 and the substrate 66, a polarizing plate 67 disposed on the surface (lower side in FIG. 7) opposite from the surface that faces the liquid crystal layer 62 of the substrate 11 of the color filter 1, and a polarizing plate 68 disposed on the side (upper side in FIG. 7) opposite from the surface that faces liquid crystal layer 62 of the substrate 66. A shared electrode 61 is disposed on the surface (the surface opposite from the surface facing the substrate 11 of the colored portions 12 and the partition wall 13) on which the colored portions 12 and the partition wall 13 of the color filter 1 are disposed. Pixel electrodes 65 are disposed in the form of a matrix in positions that correspond to the colored portions 12 of the color filter 1 on the substrate (opposing substrate) 66, facing the liquid crystal layer 62 and color filter 1. An alignment film 64 is disposed between the shared electrode 61 and the liquid crystal layer 62, and an alignment film 63 is disposed between the substrate 66 (pixel electrodes 65) and the liquid crystal layer 62.

The substrate 66 is a substrate having optical transparency with respect to visible light, and is a glass substrate, for example.

The shared electrode 61 and the pixel electrodes 65 are composed of a material having optical transparency with respect to visible light, and are ITO or the like, for example.

Although not depicted in the diagram, a plurality of switching elements (e.g., TFT: thin film transistors) is disposed so as to correspond to the pixel electrodes 65. The pixel electrodes 65 corresponding to the colored portions 12 can be used to control the transmission properties of light in areas that correspond to the colored portions 12 (pixel electrodes 65) by controlling the state of the voltage applied between the shared electrode 61 and the pixel electrodes.

In the liquid crystal display device 60, light emitted from the backlight, which is not depicted, is incident from the polarizing plate 68 side (the upper side in FIG. 7). The light that passes through the liquid crystal layer 62 and enters the colored portions 12 (12A, 12B, 12C) of the color filter 1 is emitted from the polarizing plate 67 (lower side of FIG. 7) as light having a color that corresponds to the colored portions 12 (12A, 12B, 12C).

As described above, the colored portions 12 are formed using the color filter ink 2 of the present invention and therefore have reduced variability in the characteristics between colors and between pixels. As a result, an image having reduced unevenness of color and saturation, and the like can be stably displayed in the liquid crystal display device 60.

### Electronic Device

A liquid crystal display device or another image display device (electrooptic device) 1000 having a color filter 1 such as that described above can be used in a display unit of a variety of electronic equipment.

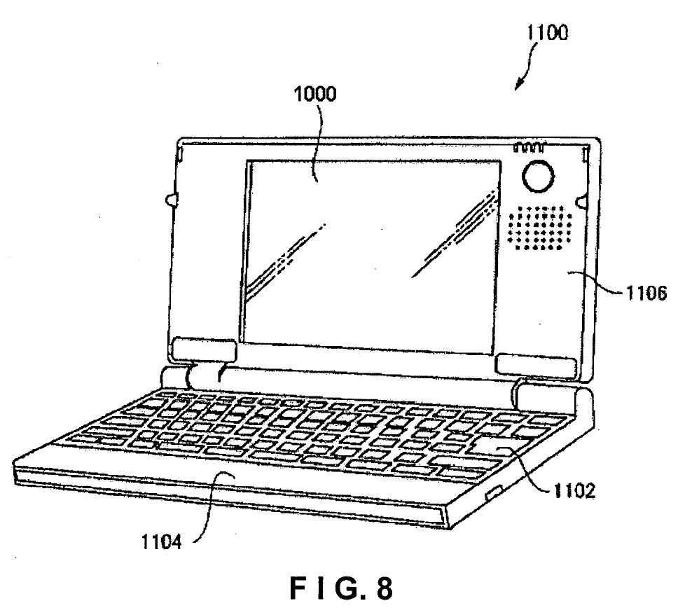

FIG. 8 is a perspective view showing the configuration of a mobile (or notebook) personal computer to which the electronic equipment of the present invention has been applied.

In the diagram, a personal computer 1100 is composed of a main unit 1104 provided with a keyboard 1102, and a display unit 1106. The display unit 1106 is rotatably supported by the main unit 1104 via a hinge structure.

In the personal computer 1100, the display unit 1106 is provided with an image display device 1000.

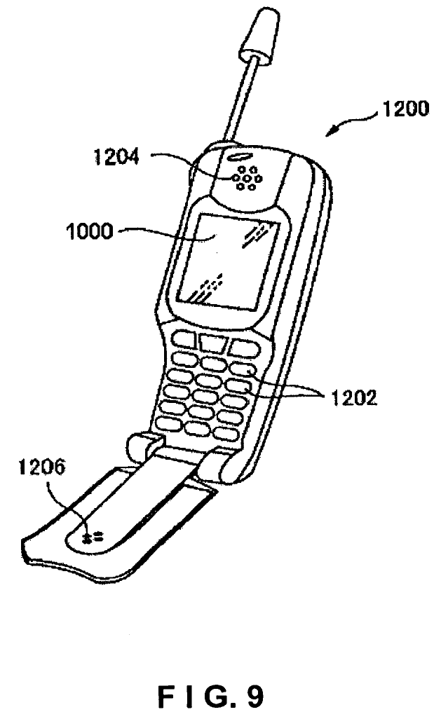

FIG. 9 is a perspective view showing the configuration of a portable telephone (including PHS) to which the electronic device of the present invention has been applied.

In the diagram, the portable telephone 1200 has a plurality of operating buttons 1202, an earpiece 1204, and a mouthpiece 1206, as well as an image display device 1000 provided to the display unit.

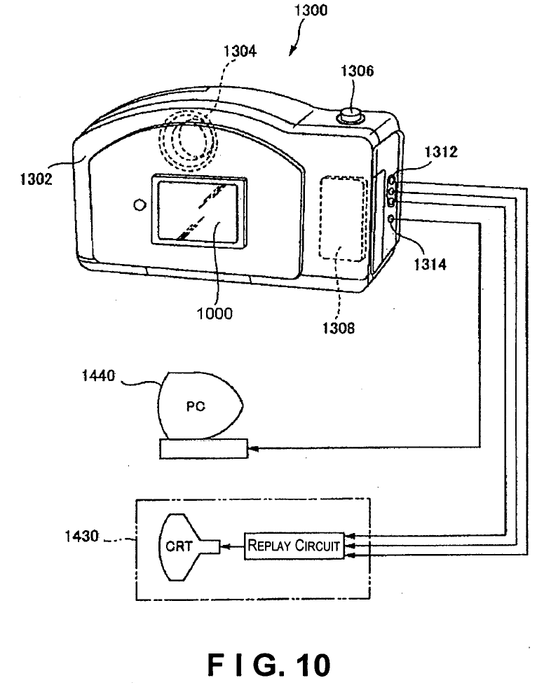

FIG. 10 is a perspective view showing the configuration of a digital still camera in which the electronic device of the present invention has been applied. In the diagram, connection to external apparatuses is displayed in a simplified manner.

In this case, an ordinary camera exposes a silver-salt photography film to the optical image of a photographed object, but in contrast, a digital still camera 1300 photoelectrically converts the optical image of a photographed image and generates an imaging signal (image signal) with the aid of a CCD (Charge Coupled Device) or another imaging element.

An image display device 1000 is disposed in the display portion on the back surface of a case (body) 1302 in the digital still camera 1300, is configured to perform display operation on the basis of a pickup signal from the CCD, and functions as a finder for displaying the photographed object as an electronic image.

A circuit board 1308 is disposed inside the case. The circuit board 1308 has a memory that can store (record) the imaging signal.

A photo-detection unit 1304 that includes an optical lens (imaging optical system), a CCD, and the like is disposed on the front surface side (back surface side in the configuration of the diagram) of the case 1302.

A photographer confirms the image of the object to be photographed displayed on the display unit, and the imaging signal of the CCD when a shutter button 1306 is pressed is transferred and stored in the memory of the circuit board 1308.

In the digital still camera 1300, a video signal output terminal 1312 and a data communication I/O terminal 1314 are disposed on the side surface of the case 1302. A television monitor 1430 is connected to the video signal output terminal 1312 as required, and a personal computer 1440 is connected to the data communication I/O terminal 1314 as required, as shown in the diagram. An imaging signal stored in the memory of the circuit board 1308 is configured to be outputted by a prescribed operation to the television monitor 1430 and the personal computer 1440.

The electronic device of the present invention may be applied to the above-described personal computer (mobile personal computer), portable telephone, and digital still camera, and other examples include televisions (e.g., liquid crystal display devices), video cameras, view finder-type and direct-view monitor-type video tape recorders, laptop personal computers, car navigation devices, pagers, electronic assistants (including those with a communication function), electronic dictionaries, calculators, electronic game devices, word processors, work stations, videophones, security television monitors, electronic binoculars, POS terminals, apparatuses having a touch panel (e.g., cash dispensers for financial institutions, and automatic ticketing machines), medical equipment (e.g., electronic thermometers, sphygmomanometers, blood glucose sensors, electrocardiograph display devices, ultrasound diagnostic devices, and endoscopic display devices), fish finders, various measuring apparatuses, instruments (e.g., instruments in vehicles, aircraft, and ships), flight simulators, and various other monitors, and projectors, and other projection display devices. Among these, televisions have display units that are tending to become markedly larger in recent years, but in electronic devices having such a large display unit (e.g., a display unit having a diagonal length of 80 cm or more), unevenness of color and saturation, and other problems particularly readily occur when a color filter manufactured using a conventional color filter ink is used. However, in accordance with the present invention, the occurrence of such problems can be reliably prevented. In other words, the effect of the present invention is more markedly demonstrated when application is made to an electronic device having a large display unit such as that described above.

The present invention above was described based on preferred embodiments, but the present invention is not limited to these embodiments.

For example, in the embodiments described above, color filter ink corresponding to the colored portions of various colors was applied inside the cells, the liquid medium was thereafter removed in a single process from the color filter ink of each color in the cells, and the resin material was cured. In other words, a process was described in which the colored portion formation step (curing step) was carried out a single time, but the ink application step and the colored portion formation step may be repeated for each color.

It is also possible to substitute or to add as another configuration the parts constituting a color filter, image display device, and electronic device with any part that demonstrates the same function. For example, in the color filter of the present invention, a protective film for covering the colored portions may be provided to the surface opposite from the surface facing the substrate of the colored portions. Damage, degradation, and the like of the colored portions can thereby be more effectively prevented.

In the embodiments described above, the case in which an ink set for a color filter is provided with three types (three colors) of color filter inks corresponding to the three primary colors of light was mainly described, but the number and type (color) of color filter inks constituting the ink set for a color filter is not limited to the arrangement described above. For example, in the present invention, the ink set for a color filter may be one provided with four or more types of color filter inks.

### EXAMPLES

Next, specific examples of the present invention will be described.

### 1. Synthesis of Polymer (Preparation of Polymer Solution)

### Synthesis Example 1

As the solvent, 37.6 parts by weight of CH₃O(CH₂CH(CH₃)O)₂CH₂CH₂CH₂CH₃ was placed in a 1-L reaction container provided with an agitator, a reflux condenser, a dropping funnel, a nitrogen introduction tube, and a temperature gauge, and heated to 90° C. Next, 2 parts by weight of 2,2′-azobis(isobutyronitrile) (AIBN) and 3 parts by weight CH₃O(CH₂CH(CH₃)O)₂CH₂CH₂CH₂CH₃ (solvent) were added, and a solution in which 27 parts by weight of (3,4-epoxy cyclohexyl) methyl methacrylate (product name: Cyclomer M100, manufactured by Daicel Chemical Industries), 1.5 parts by weight of 2-(0-[1′-methylpropylideneamino]carboxyamino)methacrylate (product name: MOI-BM, manufactured by Showa Denko), and 1.5 parts by weight of 2-hydroxy ethyl methacrylate (HEMA) were admixed was dropped over about 4 hours using a dropping pump. Also, a solution (polymerization initiator solution) in which 5 parts by weight of dimethyl 2,2′-azobis(isobutyrate) (product name V-601, manufactured by Wako Pure Chemical Industries) as the polymerization initiator were dissolved in 20 parts by weight of CH₃O(CH₂CH(CH₃)O)₂CH₂CH₂CH₂CH₃ (solvent) was dropped over about 4 hours using a separate dropping pump. After the dropping of the polymerization initiator solution was completed, 0.2 part by weight of AIBN and 1 part by weight of CH₃O(CH₂CH(CH₃)O)₂CH₂CH₂CH₂CH₃ (solvent) was added and held for about 2 hours at about the same temperature, after which 0.2 part by weight of AIBN and 1 part by weight of CH₃O(CH₂CH(CH₃)O)₂CH₂CH₂CH₂CH₃ (solvent) was added and held for about 2 hours at about the same temperature, and then cooled to room temperature to obtain a polymer solution A1 containing a polymer A and having a solid content of 30 wt %.

### Synthesis Examples 2 to 8

The same operation as synthesis example 1 described above was carried out, except that the type of monomer components, usage amount, and type of solvent used in the synthesis of the polymer (preparation of the polymer solution) were varied in the manner shown in Table 1. As a result, nine polymer solutions (polymer solutions A2 to A8) containing a polymer A and having a solid content of 30 wt % were obtained.

### Synthesis Example 9

The same operation as synthesis example 1 described above was carried out, except that 1H,1H,5H-octafluoropentyl methacrylate (product name: Biscoat 8FM, manufactured by Osaka Organic Chemical Industry) was used in place of 2-(0-[1′-methylpropylideneamino]carboxyamino)methacrylate (product name: MOI-BM, manufactured by Showa Denko) and 2-hydroxyethyl methacrylate (HEMA). As a result, a polymer solution (polymer solution B1) containing a polymer B and having a solid content of 30 wt % was obtained.

### Synthesis Examples 10 to 15

The same operation as synthesis example 9 described above was carried out, except that the type of monomer components, usage amount, and type of solvent used in the synthesis of the polymer (preparation of the polymer solution) were varied in the manner shown in Table 1. As a result, six polymer solutions (polymer solutions B2 to B7) containing a polymer B and having a solid content of 30 wt % were obtained.

### Synthesis Example 16

The same operation as synthesis example 1 described above was carried out, except that 30 parts by weight of γ-methacryloxypropyl trimethoxysilane (product name: SZ6030, manufactured by Dow Corning Toray) was used in place of (3,4-epoxy cyclohexyl) methyl methacrylate (product name: Cyclomer M100, manufactured by Daicel Chemical Industries), 2-(0-[1′-methylpropylideneamino]carboxyamino)methacrylate (product name: MOI-BM, manufactured by Showa Denko), and 2-hydroxyethyl methacrylate (HEMA). As a result, a polymer solution C1 (homopolymer solution) containing a polymer C and having a solid content of 30 wt % was obtained.

### Synthesis Examples 17 and 21

The same operation as synthesis example 16 described above was carried out, except that the type of monomer components, usage amount, and type of solvent used in the synthesis of the polymer (preparation of the polymer solution) were varied in the manner shown in Table 1. As a result, five polymer solutions (polymer solutions C2 to C6) containing a polymer C and having a solid content of 30 wt % were obtained.

The type of material and usage amount (composition of the polymer synthesized in synthesis examples 1 to 21) used in the synthesis of the polymers in the synthesis example 1 to 21 are summarized in Table 1. In the table, “M” refers to a solvent, and more particularly “M1” refers CH₃O(CH₂CH(CH₃)O)₂CH₂CH₂CH₂CH₃ (solvent), “M2” refers to CH₃O(CH₂CH(CH₃)O)₂CH₃ (solvent), “M3” refers to CH₃CH₂O(CH₂CH(CH₃)O)₂CH₂CH₃ (solvent), “M4” CH₃O(CH₂CH(CH₃)O)₂CH₂CH₂CH₂CH₂CH₃ (solvent), “M5” refers to diethylene glycol monobutyl ether acetate (solvent), “M6” refers to tripropylene glycol monomethyl ether (solvent), and “M7” refers to 1,3-butylene glycol diacetate (solvent). Also, “V-601” refers to dimethyl 2,2′-azobis(isobutyrate), “AIBN” refers to 2,2′-azobis(isobutyronitrile), “a1-1” refers to (3,4-epoxy cyclohexyl)methyl methacrylate (Cyclomer M100), “a1-2” refers to (3,4-epoxy cyclohexyl)methyl acrylate, “a2-1” refers to 2-(0-[1′-methylpropylideneamino]carboxyamino)methacrylate (MOI-BM), “a2-2” refers to 2-acryloyloxyethyl isocyanate (product name: “Karenz MOI”, manufactured by Showa Denko), “a3-1” refers to 2-hydroxy ethyl methacrylate (HEMA), “a3-2” refers to 4-hydroxybutyl acrylate, “a4-1” refers to 2-ethylhexyl methacrylate, “b1-1” refers to 1H,1H,5H-octafluoropentyl methacrylate (Biscoat 8FM), “b1-2” refers to 1,2,3,4,5-pentafluorostyrene, “b2-1” refers to (3,4-epoxy cyclohexyl)methyl methacrylate (Cyclomer M100), “b2-2” refers to cyclohexyl methacrylate, “c1-1” refers to γ-methacryloxypropyl trimethoxysilane (SZ6030), “c1-2” refers to γ-methacryloxypropyl triethoxysilane, “c2-1” refers to ethyl methacrylate. Also shown in the table are the molecular weights Mw of the polymers that constitute the polymer solutions.

TABLE 1

| | CONSTITUENT COMPONENTS (PARTS BY WEIGHT) | | | | | | | | | | | | | | | | | SOLVENT | |
|---|---|---|---|---|---|---|---|---|---|---|---|---|---|---|---|---|---|---|---|
| | MONOMER COMPONENT | | | | | | | | | | | | | | | | | (M) | POLY- |
| | a1- | a1- | a2- | a2- | a3- | a3- | a4- | b1- | b1- | b2- | b2- | c1- | c1- | c2- | | V- | | COMPO- | MER |
| | 1 | 2 | 1 | 2 | 1 | 2 | 1 | 1 | 2 | 1 | 2 | 1 | 2 | 1 | M | 601 | AIBN | SITION | Mw |
| POLYMER SOLUTION A1 | 27 | — | 1.5 | — | 1.5 | — | — | — | — | — | — | — | — | — | 62.6 | 5 | 2.4 | M1 | 2700 |
| POLYMER SOLUTION A2 | 27 | — | 3 | — | — | — | — | — | — | — | — | — | — | — | 62.6 | 5 | 2.4 | M4 | 2800 |
| POLYMER SOLUTION A3 | 27 | — | — | — | 3 | — | — | — | — | — | — | — | — | — | 62.6 | 5 | 2.4 | M3 | 2800 |
| POLYMER SOLUTION A4 | 24 | — | — | — | — | — | 6 | — | — | — | — | — | — | — | 62.6 | 5 | 2.4 | M1 | 2800 |
| POLYMER SOLUTION A5 | 19 | — | 5 | — | 4.5 | — | 1.5 | — | — | — | — | — | — | — | 62.6 | 5 | 2.4 | M5 | 2700 |
| POLYMER SOLUTION A6 | 20.5 | — | 3 | — | 5.5 | — | 1 | — | — | — | — | — | — | — | 62.6 | 5 | 2.4 | M6 | 2700 |
| POLYMER SOLUTION A7 | — | 27.5 | — | 1.5 | — | 1 | — | — | — | — | — | — | — | — | 62.6 | 5 | 2.4 | M6 | 2800 |
| POLYMER SOLUTION A8 | 27 | — | 1.5 | — | 1.5 | — | — | — | — | — | — | — | — | — | 62.6 | 5 | 2.4 | M5 + M7 | 2700 |
| POLYMER SOLUTION B1 | — | — | — | — | — | — | — | 6 | — | 24 | — | — | — | — | 62.6 | 5 | 2.4 | M1 | 2800 |
| POLYMER SOLUTION B2 | — | — | — | — | — | — | — | 2 | — | 28 | — | — | — | — | 62.6 | 5 | 2.4 | M4 | 2800 |
| POLYMER SOLUTION B3 | — | — | — | — | — | — | — | 19 | — | 11 | — | — | — | — | 62.6 | 5 | 2.4 | M6 | 2800 |
| POLYMER SOLUTION B4 | — | — | — | — | — | — | — | 30 | — | — | — | — | — | — | 62.6 | 5 | 2.4 | M1 | 2800 |
| POLYMER SOLUTION B5 | — | — | — | — | — | — | — | 4 | — | — | 26 | — | — | — | 62.6 | 5 | 2.4 | M3 | 2800 |
| POLYMER SOLUTION B6 | — | — | — | — | — | — | — | 6 | — | 24 | — | — | — | — | 62.6 | 5 | 2.4 | M5 + M7 | 2800 |
| POLYMER SOLUTION B7 | — | — | — | — | — | — | — | — | 6 | 24 | — | — | — | — | 62.6 | 5 | 2.4 | M1 | 2800 |
| POLYMER SOLUTION C1 | — | — | — | — | — | — | — | — | — | — | — | 30 | — | — | 62.6 | 5 | 2.4 | M1 | 2800 |
| POLYMER SOLUTION C2 | — | — | — | — | — | — | — | — | — | — | — | 26 | — | 4 | 62.6 | 5 | 2.4 | M4 | 2700 |
| POLYMER SOLUTION C3 | — | — | — | — | — | — | — | — | — | — | — | 23 | — | 7 | 62.6 | 5 | 2.4 | M6 | 2700 |
| POLYMER SOLUTION C4 | — | — | — | — | — | — | — | — | — | — | — | — | 30 | — | 62.6 | 5 | 2.4 | M5 | 2800 |
| POLYMER SOLUTION C5 | — | — | — | — | — | — | — | — | — | — | — | — | 28 | 2 | 62.6 | 5 | 2.4 | M3 | 2800 |
| POLYMER SOLUTION C6 | — | — | — | — | — | — | — | — | — | — | — | 30 | — | — | 62.6 | 5 | 2.4 | M5 + M7 | 2800 |

### 2. Preparation of Color Filter Ink

### Example 1

First, CH₃O(CH₂CH(CH₃)O)₂CH₂CH₂CH₂CH₃ (liquid medium) was prepared and added thereto was Disperbyk-161 (manufactured by BYK Japan, KK, a compound having a cyamelide ring) as a dispersing agent), C.I. pigment red 254 and C.I. pigment red 177 as colorants, and C.I. pigment yellow 150 as a colorant. Bead mill (zirconia beads: 0.65 mm) was introduced, the pigments were pulverized, and a pigment liquid dispersion was obtained.

Next, a red color filter ink (R ink) was prepared by adding and sufficiently mixing the pigment liquid dispersion with a mixed solution composed of 50 parts by weight of the polymer solution A1 and 50 parts by weight of the polymer solution B1 prepared in the manner described above. The average particle diameter of the C.I. pigment red 254, C.I. pigment red 177, and C.I. pigment yellow 150 in the R ink was 80 nm for each pigment.

A green color filter ink (G ink) and a blue color filter ink (B ink) were prepared in the same manner as the red color filter ink described above, except that the type of colorant and the usage amount of each component were varied. Accordingly, an ink set composed of the three colors R, G, B were obtained. The average particle diameter of the C.I. pigment green 36 and C.I. pigment yellow 150 in the G ink, and the average particle diameter of the C.I. pigment blue 15:6 in the B ink were 70 nm for each pigment. The composition of the inks constituting the ink set is shown in table 1.

### Examples 2 to 12

A color filer ink (ink set) was prepared in the same manner as embodiment 1, except that the composition of the inks constituting the ink set was set as shown in the table by varying the type and usage amount of the polymer solution were varied, and varying the type and usage amount of the components used in the preparation of the pigment liquid dispersion.

### Comparative Examples 1 to 3

Color filter ink (ink set) was prepared in the same manner as example 1, except that the composition of the inks constituting the ink set were set as shown in the table by varying the type of polymer solution and usage amount, and varying as required the types of components and usage amounts used in the preparation of the pigment liquid dispersion.

The compositions and viscosities of the color filter ink of the examples and comparative examples described above are summarized together with the liquid media in tables 2 and 3. In the tables, C.I. pigment red 254 is referred to as “PR254,” C.I. pigment red 177 is referred to as “PR177,” C.I. pigment green 36 is referred to as “PG36,” C.I. pigment blue 15:6 is referred to as “PB 15:6,” C.I. pigment yellow 150 is referred to as “PY150,” and Disperbyk-161 (dispersing agent) is referred to as “D.” Also, in tables 2 and 3, the polymer contained in the polymer solution is indicated as A1 in the resin material column. Similarly, the polymers contained in the polymer solutions A2 to A8, B1 to B7, and C1 to C6 are referred to as A2 to A8, B1 to B7, and C1 to C6 respectively. In the table, the viscosity at 25° C. of the color filter inks measured in accordance with JIS Z8809 using a vibrating viscosimeter is indicated using in the column titled “Viscosity,” the boiling point of the liquid media at normal pressure (1 atmosphere) is indicated in the column titled “Boiling Point,” and the vapor pressure of the liquid media at 25° C. is indicated in the column titled “Vapor Pressure.”

TABLE 2

| | | COLOR FILTER INK | | | | | | | | | |
|---|---|---|---|---|---|---|---|---|---|---|---|
| | | COMPOSITION | | | | | | | | | |
| | | COLORANT | | | | RESIN MATERIAL | | | | | |
| | | | CONTENT | | CONTENT | | CONTENT | | CONTENT | | CONTENT |
| | | | (PARTS BY | | (PARTS BY | | (PARTS BY | | (PARTS BY | | (PARTS BY |
| | | | WEIGHT) | | WEIGHT) | | WEIGHT) | | WEIGHT) | | WEIGHT) |
| EXAMPLE 1 | R INK | PR254/PR177 | 2.7/2.6 | PY150 | 2.0 | A1 | 1.0 | B1 | 1.0 | — | — |
| | G INK | PG36 | 7.2 | PY150 | 2.9 | A1 | 1.0 | B1 | 1.0 | — | — |
| | B INK | PB15:6 | 4.9 | — | — | A1 | 1.0 | B1 | 1.0 | — | — |
| EXAMPLE 2 | R INK | PR254/PR177 | 2.6/2.6 | PY150 | 1.9 | A2 | 1.0 | B2 | 1.0 | — | — |
| | G INK | PG36 | 7.0 | PY150 | 2.8 | A2 | 1.1 | B2 | 1.1 | — | — |
| | B INK | PB15:6 | 4.9 | — | — | A2 | 0.9 | B2 | 0.9 | — | — |
| EXAMPLE 3 | R INK | PR254/PR177 | 2.6/2.5 | PY150 | 1.9 | A3 | 1.0 | B5 | 1.0 | — | — |
| | G INK | PG36 | 7.0 | PY150 | 2.8 | A3 | 1.1 | B5 | 1.0 | — | — |
| | B INK | PB15:6 | 4.8 | — | — | A3 | 0.9 | B5 | 0.8 | — | — |
| EXAMPLE 4 | R INK | PR254/PR177 | 2.5/2.5 | PY150 | 1.9 | A1 | 0.8 | B1 | 0.7 | C1 | 0.7 |
| | G INK | PG36 | 7.3 | PY150 | 3.1 | A1 | 1.3 | B1 | 1.2 | C1 | 1.2 |
| | B INK | PB15:6 | 4.8 | — | — | A1 | 0.7 | B1 | 0.6 | C1 | 0.6 |
| EXAMPLE 5 | R INK | PR254/PR177 | 2.6/2.6 | PY150 | 2.1 | A1 | 1.3 | B7 | 0.7 | C4 | 0.2 |
| | G INK | PG36 | 7.2 | PY150 | 2.9 | A1 | 1.3 | B7 | 0.6 | C4 | 0.2 |
| | B INK | PB15:6 | 4.9 | — | — | A1 | 1.1 | B7 | 0.6 | C4 | 0.2 |
| EXAMPLE 6 | R INK | PR254/PR177 | 2.5/2.5 | PY150 | 1.9 | A4 | 1.4 | B2 | 0.7 | — | — |
| | G INK | PG36 | 7.0 | PY150 | 2.7 | A4 | 1.5 | B2 | 0.7 | — | — |
| | B INK | PB15:6 | 4.7 | — | — | A4 | 1.2 | B2 | 0.6 | — | — |
| EXAMPLE 7 | R INK | PR254/PR177 | 2.6/2.6 | PY150 | 2.1 | A5 | 1.1 | B4 | 0.9 | C5 | 0.2 |
| | G INK | PG36 | 7.4 | PY150 | 2.9 | A5 | 1.2 | B4 | 1.0 | C5 | 0.3 |
| | B INK | PB15:6 | 4.9 | — | — | A5 | 1.1 | B4 | 0.8 | C5 | 0.2 |

| | | COLOR FILTER INK | | | | | | |
|---|---|---|---|---|---|---|---|---|
| | | COMPOSITION | | | | | | |
| | | DISPERSING | | LIQUID | | | LIQUID MEDIUM | |
| | | AGENT | | MEDIUM | | | CHARACTERISTICS | |
| | | | CONTENT | | CONTENT | | BOILING | VAPOR |
| | | | (PARTS BY | | (PARTS BY | VISCOSITY | POINT | PRESSURE |
| | | | WEIGHT) | | WEIGHT) | (mPa · s) | (° C.) | (mmHg) |
| EXAMPLE 1 | R INK | D | 5.0 | M1 | 85.7 | 8.2 | 210 | 0.16 |
| | G INK | D | 4.8 | M1 | 83.1 | 8.5 | 210 | 0.16 |
| | B INK | D | 4.5 | M1 | 88.6 | 8.4 | 210 | 0.16 |
| EXAMPLE 2 | R INK | D | 4.9 | M4 | 86.0 | 8.6 | 225 | 0.10 |
| | G INK | D | 4.8 | M4 | 83.2 | 8.7 | 225 | 0.10 |
| | B INK | D | 4.5 | M4 | 88.8 | 8.4 | 225 | 0.10 |
| EXAMPLE 3 | R INK | D | 4.8 | M3 | 86.2 | 9.1 | 201 | 0.19 |
| | G INK | D | 4.7 | M3 | 83.4 | 9.2 | 201 | 0.19 |
| | B INK | D | 4.5 | M3 | 89.0 | 9.0 | 201 | 0.19 |
| EXAMPLE 4 | R INK | D | 4.8 | M1 | 86.1 | 8.3 | 210 | 0.16 |
| | G INK | D | 6.5 | M1 | 79.4 | 8.4 | 210 | 0.16 |
| | B INK | D | 5.1 | M1 | 88.2 | 8.2 | 210 | 0.16 |
| EXAMPLE 5 | R INK | D | 4.5 | M5/M1 | 51.6/34.4 | 8.7 | 225 | 0.12 |
| | G INK | D | 5.0 | M5/M1 | 49.7/33.1 | 8.9 | 225 | 0.12 |
| | B INK | D | 4.8 | M5/M1 | 53.0/35.4 | 8.8 | 225 | 0.12 |
| EXAMPLE 6 | R INK | D | 4.7 | M3/M4 | 69.0/17.3 | 8.7 | 206 | 0.17 |
| | G INK | D | 5.1 | M3/M4 | 66.4/16.6 | 8.9 | 206 | 0.17 |
| | B INK | D | 4.9 | M3/M4 | 70.9/17.7 | 8.9 | 206 | 0.17 |
| EXAMPLE 7 | R INK | D | 4.8 | M2 | 85.7 | 8.7 | 215 | 0.14 |
| | G INK | D | 5.2 | M2 | 82.0 | 8.6 | 215 | 0.14 |
| | B INK | D | 4.6 | M2 | 88.4 | 8.4 | 215 | 0.14 |

TABLE 3

| | | COLOR FILTER INK | | | | | | | | | |
|---|---|---|---|---|---|---|---|---|---|---|---|
| | | COMPOSITION | | | | | | | | | |
| | | | | | | RESIN MATERIAL | | | | | |
| | | | | | | | | | | | CON- |
| | | COLORANT | | | | | | | | | TENT |
| | | | CONTENT | | CONTENT | | CONTENT | | CONTENT | | (PARTS |
| | | | (PARTS BY | | (PARTS BY | | (PARTS BY | | (PARTS BY | | BY |
| | | | WEIGHT) | | WEIGHT) | | WEIGHT) | | WEIGHT) | | WEIGHT) |
| EXAMPLE 8 | R INK | PR254/PR177 | 2.6/2.5 | PY150 | 1.9 | A6 | 0.8 | B2 | 0.8 | C2 | 0.4 |
| | G INK | PG36 | 7.5 | PY150 | 2.8 | A6 | 0.9 | B2 | 0.9 | C2 | 0.4 |
| | B INK | PB15:6 | 4.8 | — | — | A6 | 0.8 | B2 | 0.7 | C2 | 0.4 |
| EXAMPLE 9 | R INK | PR254/PR177 | 2.6/2.5 | PY150 | 1.9 | A7 | 0.7 | B3 | 0.9 | C3 | 1.3 |
| | G INK | PG36 | 7.3 | PY150 | 2.0 | A7 | 0.7 | B3 | 0.8 | C3 | 1.3 |
| | B INK | PB15:6 | 4.9 | — | — | A7 | 0.5 | B3 | 0.5 | C3 | 0.8 |
| EXAMPLE 10 | R INK | PR254/PR177 | 2.7/2.6 | PY150 | 2.0 | A1 | 1.6 | B1 | 0.4 | — | — |
| | G INK | PG36 | 7.2 | PY150 | 2.9 | A1 | 1.6 | B1 | 0.4 | — | — |
| | B INK | PB15:6 | 4.9 | — | — | A1 | 1.6 | B1 | 0.4 | — | — |
| EXAMPLE 11 | R INK | PR254/PR177 | 2.7/2.6 | PY150 | 2.0 | A1 | 0.4 | B1 | 1.6 | — | — |
| | G INK | PG36 | 7.2 | PY150 | 2.9 | A1 | 0.4 | B1 | 1.6 | — | — |
| | B INK | PB15:6 | 4.9 | — | — | A1 | 0.4 | B1 | 1.6 | — | — |
| EXAMPLE 12 | R INK | PR254/PR177 | 2.5/2.5 | PY150 | 1.9 | A8 | 0.8 | B6 | 0.7 | C6 | 0.7 |
| | G INK | PG36 | 7.3 | PY150 | 3.1 | A8 | 1.3 | B6 | 1.2 | C6 | 1.2 |
| | B INK | PB15:6 | 4.8 | — | — | A8 | 0.7 | B6 | 0.6 | C6 | 0.6 |
| COMPARATIVE | R INK | PR254/PR177 | 2.7/2.6 | PY150 | 2.0 | A1 | 2.0 | — | — | — | — |
| EXAMPLE 1 | G INK | PG36 | 7.2 | PY150 | 2.9 | A1 | 2.0 | — | — | — | — |
| | B INK | PB15:6 | 4.9 | — | — | A1 | 2.0 | — | — | — | — |
| COMPARATIVE | R INK | PR254/PR177 | 2.7/2.6 | PY150 | 2.0 | — | — | B1 | 2.0 | — | — |
| EXAMPLE 2 | G INK | PG36 | 7.2 | PY150 | 2.9 | — | — | B1 | 2.0 | — | — |
| | B INK | PB15:6 | 4.9 | — | — | — | — | B1 | 2.0 | — | — |
| COMPARATIVE | R INK | PR254/PR177 | 2.7/2.6 | PY150 | 2.0 | — | — | B4 | 2.0 | — | — |
| EXAMPLE 3 | G INK | PG36 | 7.2 | PY150 | 2.9 | — | — | B4 | 2.0 | — | — |
| | B INK | PB15:6 | 4.9 | — | — | — | — | B4 | 2.0 | — | — |

| | | COLOR FILTER INK | | | | | | |
|---|---|---|---|---|---|---|---|---|
| | | COMPOSITION | | | | | | |
| | | DISPERSING | | LIQUID | | | LIQUID MEDIUM | |
| | | AGENT | | MEDIUM | | | CHARACTERISTICS | |
| | | | CONTENT | | CONTENT | | BOILING | VAPOR |
| | | | (PARTS BY | | (PARTS BY | VISCOSITY | POINT | PRESSURE |
| | | | WEIGHT) | | WEIGHT) | (mPa · S) | (° C.) | (mmHg) |
| EXAMPLE 8 | R INK | D | 4.8 | M4 | 86.2 | 8.2 | 225 | 0.10 |
| | G INK | D | 4.9 | M4 | 82.6 | 8.3 | 225 | 0.10 |
| | B INK | D | 4.9 | M4 | 88.4 | 8.0 | 225 | 0.10 |
| EXAMPLE 9 | R INK | D | 5.4 | M6 | 84.7 | 8.6 | 242 | 0.07 |
| | G INK | D | 5.0 | M6 | 82.9 | 8.5 | 242 | 0.07 |
| | B INK | D | 4.9 | M6 | 88.4 | 8.3 | 242 | 0.07 |
| EXAMPLE 10 | R INK | D | 5.0 | M1 | 85.7 | 8.2 | 210 | 0.16 |
| | G INK | D | 4.8 | M1 | 83.1 | 8.5 | 210 | 0.16 |
| | B INK | D | 4.5 | M1 | 88.6 | 8.4 | 210 | 0.16 |
| EXAMPLE 11 | R INK | D | 5.0 | M1 | 85.7 | 8.2 | 210 | 0.16 |
| | G INK | D | 4.8 | M1 | 83.1 | 8.5 | 210 | 0.16 |
| | B INK | D | 4.5 | M1 | 88.6 | 8.4 | 210 | 0.16 |
| EXAMPLE 12 | R INK | D | 4.8 | M5/M7 | 12.9/73.2 | 8.3 | — | — |
| | G INK | D | 6.5 | M5/M7 | 11.9/67.5 | 8.4 | — | — |
| | B INK | D | 5.1 | M5/M7 | 13.2/75.0 | 8.2 | — | — |
| COMPARATIVE | R INK | D | 5.0 | M1 | 85.7 | 8.2 | 210 | 0.16 |
| EXAMPLE 1 | G INK | D | 4.8 | M1 | 83.1 | 8.5 | 210 | 0.16 |
| | B INK | D | 4.5 | M1 | 88.6 | 8.4 | 210 | 0.16 |
| COMPARATIVE | R INK | D | 5.0 | M1 | 85.7 | 8.2 | 210 | 0.16 |
| EXAMPLE 2 | G INK | D | 4.8 | M1 | 83.1 | 8.5 | 210 | 0.16 |
| | B INK | D | 4.5 | M1 | 88.6 | 8.4 | 210 | 0.16 |
| COMPARATIVE | R INK | D | 5.0 | M1 | 85.7 | 8.2 | 210 | 0.16 |
| EXAMPLE 3 | G INK | D | 4.8 | M1 | 83.1 | 8.5 | 210 | 0.16 |
| | B INK | D | 4.5 | M1 | 88.6 | 8.4 | 210 | 0.16 |

### 3. Evaluation of Stability of Droplet Discharge (Evaluation of Stable Discharge Properties)

### (3.1) Evaluation of Landing Position Accuracy

A droplet discharge device such as that shown in FIGS. 3 to 6 disposed in a chamber (thermal chamber) and the ink sets for a color filter of the examples and comparative examples were prepared, and 50,000 droplets (50,000 drops) of the inks were continuously discharged from the nozzles of a droplet discharge head in a state in which the drive waveform of the piezoelement had been optimized. The average value of the offset distance d from the center aim position of the center position of the landed droplets was calculated for the 50,000 droplets discharged from specified nozzles in the vicinity of the center of the droplet discharge head, and an evaluation was made based on the four ranges described below. The average value of the values obtained for three color-inks was used as the average value of the offset distance d. It is apparent that the smaller this value is, the more effectively prevented the occurrence of flight deflection is.

A: The average value of the offset distance d is less than 0.03 μm

B: The average value of the offset distance d is 0.03 μm or more and less than 0.08 μm

C: The average value of the offset distance d is 0.08 μm or more and less than 0.12 μm

D: The average value of the offset distance d is 0.12 or more

### (3.2) Evaluation of Stability of Droplet Discharge Quantity

A droplet discharge device such as that shown in FIGS. 3 to 6 disposed in a chamber (thermal chamber), and the ink sets for a color filter of the examples and comparative examples were prepared, and 50,000 droplets (50,000 drops) of the inks were continuously discharged from the nozzles of a droplet discharge head in a state in which the drive waveform of the piezoelement had been optimized. The total weight of the discharged droplets was calculated for two specific nozzles at the left and right ends of the droplet discharge head, and the absolute value ΔW (ng) of the difference between the average discharge quantities of the droplets discharged from the two nozzles was calculated. The ratio (ΔW/W_{T}) of the ΔW in relation to the target discharge quantity W_{T} (ng) of the droplets was calculated, and an evaluation was made based on the four ranges described below. It is apparent that the smaller the value of ΔW/W_{T} is, the greater the stability of the droplet discharge quantity. The average value of the values obtained for three color-inks was used as the value of ΔW/W_{T}.

A: The value of ΔW/W_{T} is less than 0.020

B: The value of ΔW/W_{T} is 0.020 or higher and less than 0.420

C: The value of ΔW/W_{T} is 0.420 or higher and less than 0.720

D: The value of ΔW/W_{T} is 0.720 or higher

### (3.3) Evaluation of Intermittent Printing Performance

A droplet discharge device such as that shown in FIGS. 3 to 6 disposed in a chamber (thermal chamber), and the ink sets for a color filter of the examples and comparative examples were prepared, and 5000 droplets (5000 drops) of the inks were continuously discharged from the nozzles of a droplet discharge head in a state in which the drive waveform of the piezoelement had been optimized, after which droplet discharge was stopped for 30 seconds (first sequence). Thereafter, droplets were continuously discharged in the same manner and the operation of stopping the discharge of droplets was repeated. The average weight W₁ (ng) of the droplets discharged in the first sequence and the average weight W₂₀ (ng) of the droplets discharged in the 20^{th} sequence were calculated for the specified nozzles in the vicinity of the center of the droplet discharge head. The ratio (|W₁−W₂₀)|/W_{T}) of the absolute value of the difference between W₁ and W₂₀ in relation to the target discharge quantity W_{T} (ng) of the droplets was calculated, and an evaluation was made based on the three ranges described below. It is apparent that the smaller the value of |W₁−W₂₀|/W_{T} is, the greater the intermittent printing performance (stability of the droplet discharge quantity). The average value of the values obtained for three color-inks was used as the value of |W₁−W₂₀|/W_{T}.

A: The value of |W₁−W₂₀|/W_{T} is less than 0.025

B: The value of |W₁−W₂₀|/W_{T} is 0.025 or higher and less than 0.625

C: The value of |W₁−W₂₀|/W_{T} is 0.625 or higher

### (3.4) Continuous Discharge Test

The inks constituting the ink set for a color filter were discharged by continuously operating the droplet discharge device for 36 hours in an environment of 40% RH using a droplet discharge device such as that shown in FIGS. 3 to 6 disposed in a chamber (thermal chamber) and the ink sets for a color filter of the examples and comparative examples.

The rate ([(number of clogged nozzles)/(total number of nozzles)]×100) at which clogging of the nozzles constituting the droplet discharge head occurs after continuous operation was calculated, and it was investigated whether clogging can be eliminated using a cleaning member composed of a plastic material. The results were evaluated based on the four ranges described below. The average value of the values obtained for three color-inks was used as the value of the nozzle clogging occurrence rate.

A: Nozzle clogging does not occur.

B: The occurrence rate of nozzle clogging is less than 0.5% (not including 0), and clogging can be eliminated by cleaning.

C: The occurrence rate of nozzle clogging is 0.5% or higher and less than 1.0%, and clogging can be eliminated by cleaning.

D: The occurrence rate of nozzle clogging is 1.0% or higher, and clogging cannot be eliminated by cleaning.

The evaluation described above was carried out in the same conditions for the examples and the comparative examples.

### 4. Manufacture of Color Filters

A color filter was manufactured in the following manner using the color filter inks (ink sets) prepared in the in the examples and the comparative examples.

First, a substrate (G5 size: 100×1300 mm) composed of soda glass on which a silica (SiO₂) film for preventing elution of the sodium ions was formed on the two sides was prepared and washed.

Next, a radiation-sensitive composition for forming a partition wall containing carbon black was applied to the entire surface of one of the surfaces of the washed substrate to form a coated film.

Next, a prebaking treatment was performed at a heating temperature of 110° C. and a heating time of 120 seconds.

The substrate was thereafter irradiated via a photomask, subjected to post exposure baking (PEB), subsequently developed using an alkali development fluid, and then subjected to a post baking treatment to thereby form a partition wall. PEB was carried out at a heating temperature of 110° C., a heating time of 120 seconds, and an irradiation intensity of 150 mJ/cm². The development treatment time was set to 60 seconds. The post baking treatment was carried out at a heating temperature of 150° C. for heating time of 5 minutes. The thickness of the partition wall thus formed was 2.1 μm.

Next, the color filter ink was discharged into the cells as areas surrounded by the partition wall by using a droplet discharge device such as that shown in FIGS. 3 to 6. In this case, three color filter inks were used and care was taken that the color filter ink of each color was not mixed. A droplet discharge head was used in which the nozzle plate had been joined using an epoxy adhesive (AE-40, manufactured by Ajinomoto Fine-Techno).

Thereafter, heat treatment is carried out for 10 minutes at 100° C. on a hot plate, and heat treatment was then carried out for one hour in an oven at 200° C., whereby three colored portions were formed. A color filter such as that shown in FIG. 1 was thereby obtained.

The color filter inks (ink sets) of the examples and the comparative examples were used to manufacture 3000 color filters of each ink set using the method described above.

### 5. Evaluation of Color Filters

The color filters obtained in the manner described above were evaluated in the manner described below

### (5.1) Unevenness of Color and Saturation

Among the color filters manufactured using the color filter inks (ink sets) of the examples and the comparative examples, a liquid crystal display device such as that shown in FIG. 7 was manufactured under the same conditions using the 3000^{th} color filter manufactured of each example and the comparative example.

Red monochromatic display, green monochromatic display, blue monochromatic display, and white monochromatic display were visually observed in a darkroom using these liquid crystal display devices and the occurrence of uneven color and uneven saturation between different regions was evaluated based on the five levels described below.

A: Uneven color and uneven saturation were not observed.

B: Uneven color and uneven saturation were substantially not observed.

C: Some uneven color and uneven saturation was observed.

D: Uneven color and uneven saturation were plainly observed.

E: Uneven color and uneven saturation were markedly observed.

### (5.2) Difference in Characteristics Between Units

Of the color filters manufactured using the color filter inks (ink sets) of the examples and the comparative examples, the first to the 10^{th} and the 2990^{th} to the 2999^{th} color filters manufactured of each example and the comparative example were prepared, red monochromatic display, green monochromatic display, blue monochromatic display, and white monochromatic display were carried out in a darkroom, and the colors were measured using a spectrophotometer (MCPD 3000, manufactured by Otsuka Electronics). The maximum color differences (color difference ΔE in the Lab display system) in the first to the 10^{th} and the 2990^{th} to the 2999^{th} color filters manufactured for each of the examples and comparative examples were calculated from the results and evaluated based on the five ranges described below.

A: Color difference (ΔE) is less than 2.

B: Color difference (ΔE) is 2 or more and less than 3.

C: Color difference (ΔE) is 3 or more and less than 4.

D: Color difference (ΔE) is 4 or more and less than 5.

E: Color difference (ΔE) is 5 or more.

### (5.3) Durability

Among the color filters manufactured using the color filter inks (ink sets) of the examples and the comparative examples, a liquid crystal display device such as that shown in FIG. 7 was manufactured under the same conditions using the 11^{th} to 20^{th} color filters manufactured of each example and the comparative example.

Red monochromatic display, green monochromatic display, and blue monochromatic display were visually observed in a darkroom using these liquid crystal display devices and the occurrence of the leakage (white spots, luminescent spots) of light was checked.

Next, the color filters were removed from the liquid crystal display devices.

The color filters thus removed were left sitting for 1.5 hours at 20° C., then 2 hours at 60° C., subsequently 1.5 hours at 20° C., and then 3 hours at −10° C. Thereafter, the environment temperature was again restored to 20° C. to complete a single cycle (8 hours), and this cycle was repeated for a total of 30 times (total of 240 hours).

Thereafter, liquid crystal display devices such as the one shown in FIG. 7 were again assembled using these color filters.

Red monochromatic display, green monochromatic display, and blue monochromatic display were visually observed in a darkroom using these liquid crystal display devices and the occurrence of the leakage (white spots, luminescent spots) of light was evaluated based on the following five levels.

A: There was no color filter in which leakage (white spots, luminescent spots) of light occurred.

B: Leakage (white spots, luminescent spots) of light was observed in 1 to 2 color filters.

C: Leakage (white spots, luminescent spots) of light was observed in 3 to 5 color filters.

D: Leakage (white spots, luminescent spots) of light was observed in 6 to 9 color filters.

E: Leakage (white spots, luminescent spots) of light was observed in 10 color filters.

### 6. Evaluation of Contrast

Red colored films were each formed by an inkjet method on a different glass plate (diameter: 10 cm) using the R inks constituting the ink sets of the examples and comparative examples.

The colored films were formed by discharging droplets onto the glass plates, and thereafter carrying out a heat treatment for 10 minutes at 100° C. on a hot plate, and then carrying out a heat treatment for one hour in an oven at 200° C. The discharge quantity of the color filter ink was adjusted so that the thickness of the formed colored film was 1.5 μm.

The contrast (CR) was obtained for the glass substrates on which a colored film was formed in this manner using a contrast tester (CT-1, manufactured by Tsubosaka Electric), and evaluated based on the three ranges described below.

A: CR was 2500 or higher.

B: CR was 2000 or higher and less than 2500.

C: CR was less than 2000.

Colored films for the G inks and B inks constituting the ink sets of the examples and the comparative examples were formed by the inkjet method on glass plates (diameter: 10 cm) in the same manner as above, and the contrast was obtained for the glass plates on which the colored films had been formed.

The glass plates on which the green colored films had been formed were evaluated based on the three ranges described below.

A: CR was 3500 or higher.

B: CR was 3000 or higher and less than 3500.

C: CR was less than 3000.

The glass plates on which the blue colored films had been formed were evaluated based on the three ranges described below.

A: CR was 2800 or higher.

B: CR was 2400 or higher and less than 2800.

C: CR was less than 2400.

In the evaluation described above, the color filters were observed and measured in the same conditions.

The results are shown in Table 4.

TABLE 4

| | EVALUATION OF DROPLET DISCHARGE PROPERTIES | | | | | | | | | |
|---|---|---|---|---|---|---|---|---|---|---|
| | | | | CON- | UNEVEN | DIFFERENCE | | | | |
| | | STABILITY OF | | TINUOUS | COLOR | IN CHARAC- | | | | |
| | LANDING | DROPLET | INTERMITTENT | DIS- | AND | TERISTICS | | CONTRAST | | |
| | POSITION | DISCHARGE | PRINTING | CHARGE | SATU- | BETWEEN | DURA- | RED | GREEN | BLUE |
| | ACCURACY | QUANTITY | PERFORMANCE | TEST | RATION | UNITS | BILITY | (R) | (G) | (B) |
| EXAMPLE 1 | A | A | A | A | A | A | A | A | A | A |
| EXAMPLE 2 | A | A | A | B | A | A | A | A | A | A |
| EXAMPLE 3 | A | A | A | A | A | A | A | A | A | A |
| EXAMPLE 4 | A | A | A | A | A | A | A | A | A | A |
| EXAMPLE 5 | A | A | A | A | A | A | A | A | A | A |
| EXAMPLE 6 | A | A | B | B | A | A | A | A | A | A |
| EXAMPLE 7 | A | A | A | A | A | B | A | A | A | A |
| EXAMPLE 8 | A | B | B | B | A | A | A | A | A | A |
| EXAMPLE 9 | B | A | B | A | A | A | B | A | A | A |
| EXAMPLE 10 | A | A | B | A | A | A | A | A | A | A |
| EXAMPLE 11 | A | A | A | A | A | A | B | A | A | A |
| EXAMPLE 12 | A | A | A | A | A | A | A | A | A | A |
| COMPARATIVE | C | C | C | D | C | D | E | C | C | C |
| EXAMPLE 1 | | | | | | | | | | |
| COMPARATIVE | B | C | C | C | C | E | D | C | C | C |
| EXAMPLE 2 | | | | | | | | | | |
| COMPARATIVE | C | B | C | C | D | E | D | C | C | C |
| EXAMPLE 3 | | | | | | | | | | |

In the present invention, unevenness of color and saturation among regions was suppressed in the color filters thus manufactured having excellent droplet discharge stability and the variability between units was also low, as shown in Table 4. In the present invention, the durability of the color filter was excellent. In the present invention, the contrast was excellent. On the other hand, satisfactory results were not obtained in the comparative examples.

Commercially available liquid crystal televisions were disassembled, the liquid crystal display device portions were exchanged with those manufactured in the manner described above. The same evaluation as that described above was carried out and the same results as those described above were obtained.

Color filters were prepared and color filters were manufactured in the same manner as the examples and comparative examples, except that dyes were used in place of pigments as the colorants. These color filters were evaluated in the same manner as described above and the same results as those described above were obtained. These color filters were irradiated with light at 25° C. for 200 hours at 320 W/m² using a xenon fade meter (Atlas CI-5000), the color difference (color difference ΔE in the Lab display system) before and after irradiation with light was calculated, and the light stability of the color filters was evaluated. As a result, excellent light stability was obtained in the present invention, but the color filter of comparative example 3 had inferior light stability.

### General Interpretation of Terms

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives. Finally, terms of degree such as “substantially”, “about” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents.

1. A color filter ink adapted to be used to manufacture a color filter by an inkjet method, the color filter ink comprising:
a colorant;
a resin material; and
a liquid medium that dissolves and/or disperses the colorant,
the resin material including a first polymer and a second polymer with
the first polymer including at least a first epoxy-containing vinyl monomer as a monomer component and not including a fluoroalkyl- or fluoroaryl-containing vinyl monomer represented by a chemical formula (1) below as a monomer component,
the second polymer including at least the fluoroalkyl- or fluoroaryl-containing vinyl monomer represented by the chemical formula (1) below as a monomer component, 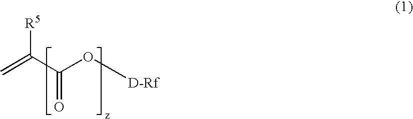
wherein, in the chemical formula (1), R⁵ represents a hydrogen atom or a C₁₋₇ alkyl group, D represents a single bond hydrocarbon group, a bivalent hydrocarbon group, or a bivalent hydrocarbon group having a hetero atom, Rf represents a C₁₋₂₀ fluoroalkyl group or fluoroaryl group, and a value z is 0 or 1.

2. The color filter ink according to claim 1, wherein
the first polymer is a copolymer having the first epoxy-containing vinyl monomer and a second vinyl monomer as monomer components, the second vinyl monomer having an isocyanate group or a block isocyanate group in which an isocyanate group is protected by a protective group.

3. The color filter ink according to claim 2, wherein
the first polymer includes 2 to 20 parts by weight of the second vinyl monomer with respect to 100 parts by weight of the first epoxy-containing vinyl monomer.

4. The color filter ink according to claim 1, wherein
the first polymer is a copolymer having the first epoxy-containing vinyl monomer and a third vinyl monomer as monomer components, the third vinyl monomer having a hydroxyl group.

5. The color filter ink according to claim 4, wherein
the first polymer includes 2 to 20 parts by weight of the third vinyl monomer with respect to 100 parts by weight of the first epoxy-containing vinyl monomer.

6. The color filter ink according to claim 1, wherein
a ratio of a content of the first polymer to a content of the second polymer is 25:75 to 75:25 in terms of weight.

7. The color filter ink according to claim 1, wherein
the liquid medium includes a compound having a propylene glycol backbone and alkoxy groups at both terminal ends of the propylene glycol backbone.

8. The color filter ink according to claim 1, wherein
the liquid medium includes a mixture of 1,3-butylene glycol diacetate and diethylene glycol monobutyl ether acetate, with a content ratio of 1,3-butylene glycol diacetate and diethylene glycol monobutyl ether acetate being 75:25 to 98:2 in terms of weight.

9. The color filter ink according to claim 1, wherein
a content ratio of the colorant in the color filter ink is 2 to 25 wt %.

10. The color filter ink according to claim 1, further comprising
a dispersing agent including a compound having a cyamelide backbone,
the colorant including a pigment.

11. A color filter manufactured using the color filter ink according to claim 1.

12. An image display device having the color filter according to claim 11.

13. The image display device according to claim 12, wherein
the image display device is a liquid crystal panel.

14. An electronic device having the image display device according to claim 12.
